(19) United States
(12) Patent Application Publication
(10) Pub. No.: US 2005/0230716 A1
(43) Pub. Date: Oct. 20, 2005

(54) Semiconductor integrated circuit equipment and its manufacture method

(75) Inventors: Satoshi Moriya, Akishima (JP); Toshiyuki Kikuchi, Ome (JP); Akihiko Konno, Hamura (JP); Hidenori Sato, Ome (JP); Naoki Yamamoto, Kawaguchi (JP); Masamichi Matsuoka, Takarazuka (JP); Hiraku Chakihara, Hitachinaka (JP); Akio Nishida, Toyonoka (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 11/107,888

(22) Filed: Apr. 18, 2005

(30) Foreign Application Priority Data
Apr. 19, 2004 (JP) 2004-122428

(51) Int. Cl. H01L 29/76; H01L 21/336

(52) U.S. Cl. 257/288; 438/197

(57) ABSTRACT

The object of the present invention is to suppress the increase of the contact resistance at the interface between the metal layer and the silicon plug in the wiring structure in which a metal layer is formed on and connected to a silicon plug. For its achievement, a lower semiconductor layer (drain) of a vertical-type MISFET is connected to an intermediate metal layer via an underlying plug composed of a polycrystalline silicon film, and a trap layer composed of a silicon nitride (TiN) film is formed on a part of the surface of the intermediate metal layer so as to surround the plug. The trap layer is formed in order to prevent an undesired high-resistance oxide layer from being formed at the interface between the plug and the intermediate metal layer.

### CROSS-REFERENCE TO RELATED APPLICATION

The present application claims priority from Japanese Patent Application JP 2004-122428 filed on Apr. 19, 2004, the content of which is hereby incorporated by reference into this application.

### TECHNICAL FIELD OF THE INVENTION

The present invention relates to a semiconductor integrated circuit device and manufacturing technology thereof. More particularly, the present invention relates to a technique effectively applied to a semiconductor integrated circuit device having wiring structure in which a silicon plug is laminated on a surface of metal wiring formed on a semiconductor substrate.

### BACKGROUND OF THE INVENTION

In the SRAM (Static Random Access Memory) which is a type of a large-capacity semiconductor memory, a memory cell is comprised of four n channel MISFETs (Metal Insulator Field Effect Transistor) and two p channel MISFETs.

However, in this type of SRAM, that is, in the so-called complete CMOS (Complementary Metal Oxide Semiconductor) type SRAM, the six MISFETs are arranged on the same plane of a main surface of a semiconductor substrate. Therefore, it is difficult to reduce the size of a memory cell. Also, since the p type well region and the n type well region for forming the CMOS and the well isolation region for isolating the p type well region and the n type well region are required, it is more difficult to reduce the size of a memory cell.

In such a circumstance, the technique for reducing the memory size is described in the Japanese Patent Application Laid-Open No. 8-88328, in which some of the six MISFETs constituting the memory cell of the SRAM are comprised of vertical-type MISFETs. The vertical-type MISFET described therein has a vertical structure in which a channel is formed on a sidewall of trench formed in a semiconductor substrate and the gate is formed by embedding the trench.

### SUMMARY OF THE INVENTION

For the purpose of reducing the memory size of the complete CMOS type SRAM comprised of four n channel MISFETs and two p channel MISFETs, the inventors of the present invention have invented the memory cell structure in which the vertical-type MISFETs are used as the two p channel MISFETs and the two vertical-type MISFETS are arranged on the four n channel MISFETs (Japanese Patent Application No. 2003-97210).

Of the six MISFETs constituting the memory cell, two transfer MISFETs and two driver MISFETs which are n channel MISFETs are formed on the main surface of the p type well. On the other hand, the two vertical-type MISFETs which are the p channel MISFETs are comprised of a laminated body in a shape of rectangular column formed by laminating a lower semiconductor layer (drain), an intermediate semiconductor layer, and an upper semiconductor layer (source), and a gate electrode composed of a p type silicon film formed on a sidewall of the laminated body via a gate insulating film. The lower semiconductor layer (drain), the intermediate semiconductor layer, and the upper semiconductor layer (source) are composed of a silicon film, and the silicon films constituting the lower semiconductor layer and the upper semiconductor layer are doped with a p type impurity.

The lower semiconductor layer (drain) of the vertical-type MISFET is connected to the intermediate metal layer via an underlying and is further connected via the intermediate metal layer to a semiconductor region (one of source and drain) shared by the transfer MISFET and the driver MISFET and the gate electrode of the driver MISFET. The plug connecting the lower semiconductor layer (drain) of the vertical-type MISFET and the intermediate metal layer is composed of a p type silicon film so as to be matched with the lower semiconductor layer (drain) of the vertical-type MISFET composed of a p type silicon film. Also, the intermediate metal layer is composed of a tungsten (W) film. This intermediate metal layer is formed in the trench formed in the insulating film in order to reduce the unevenness of the surface on which the vertical-type MISFET is formed. The two layers of metal wirings which constitute the power supply voltage line, the complementary data line, the word line, and the reference voltage line are arranged on the vertical-type MISFET.

However, in the above-described memory cell structure in which the p channel MISFETs (two vertical-type MISFETs) are arranged on the n channel MISFETs (two transfer MISFETs and two driver MISFETs) via the intermediate metal layer and the silicon plug, when the thermal treatment in the process for forming the p channel MISFET, for example, the thermal treatment for forming a gate insulating film on a sidewall of the laminated body is performed, the plug (silicon) formed below the laminated body is thermally reacted with the intermediate metal layer (W), and the contact resistance at the interface therebetween is increased by several K Ω to several M Ω.

As a result of the analysis by the inventors of the present invention, it has been found that the above-described increase is caused by the high-resistance oxide film formed in the following manner. That is, at the time of the thermal treatment, the water desorbed in the insulating film around the trench in which the intermediate metal layer is formed moves along the surface of the intermediate metal layer and penetrates into the interface between the plug and the intermediate metal layer, and then, a high-resistance oxide layer is formed.

An object of the present invention is to provide a technique capable of suppressing the increase of the contact resistance at the interface between a metal layer and a silicon plug in the wiring structure in which the silicon plug is formed on and connected to the metal layer.

The above and other objects and novel characteristics of the present invention will be apparent from the description and the accompanying drawings of this specification.

The typical ones of the inventions disclosed in this application will be briefly described as follows.

A semiconductor integrated circuit device according to the present invention comprises: metal wiring formed in a trench formed in a first insulating film on a semiconductor substrate; and a plug composed of a conductive film mainly made of silicon in a contact hole formed in a second insulating film on the metal wiring, wherein a bottom portion of the plug is in direct contact with a part of a surface of the metal wiring, and a trap layer for suppressing a reaction between the silicon constituting the plug and metal constituting the metal wiring is provided on the surface of the metal wiring in a region around the plug.

According to the method described above, even when the water desorbed in the first insulating film around the trench in which the metal wiring is formed moves along the surface of the metal wiring in the thermal treatment performed in the manufacturing process, the water is captured by a trap layer formed on the surface of the metal wiring in the region surrounding the plug. Therefore, the water does not penetrate into the interface between the plug and the metal wiring. The trap layer itself is preferably formed of a material easily reacted with water, for example, titanium nitride (TiN) and the like.

The effect obtained by the representative one of the inventions disclosed in this application will be briefly described as follows.

Since the trap layer is formed on the surface of the metal wiring in a region surrounding the silicon plug, the penetration of water into the interface between the plug and the metal wiring can be prevented in the thermal treatment performed in the manufacturing process. Consequently, since the high-resistance oxide layer is not formed at the interface between the silicon plug and the metal wiring, the increase of the contact resistance between the silicon plug and the metal wiring can be suppressed.

### BRIEF DESCRIPTIONS OF THE DRAWINGS

FIG. 1 is an equivalent circuit diagram of a memory cell of the SRAM according to an embodiment of the present invention;

FIG. 2 is a plan view showing the principal part of the SRAM according to an embodiment of the present invention;

FIG. 3 is a cross-sectional view showing the principal part of the SRAM according to an embodiment of the present invention;

FIG. 4 is a plan view showing the principal part in the manufacturing method of the SRAM according to an embodiment of the present invention;

FIG. 5 is a cross-sectional view showing the principal part in the manufacturing method of the SRAM according to an embodiment of the present invention;

FIG. 6 is a cross-sectional view showing the principal part in the manufacturing method of the SRAM subsequent to FIGS. 4 and 5;

FIG. 7 is a plan view showing the principal part in the manufacturing method of the SRAM subsequent to FIG. 6;

FIG. 8 is a cross-sectional view showing the principal part in the manufacturing method of the SRAM subsequent to FIG. 6;

FIG. 9 is a plan view showing the principal part in the manufacturing method of the SRAM subsequent to FIGS. 7 and 8;

FIG. 10 is a cross-sectional view showing the principal part in the manufacturing method of the SRAM subsequent to FIGS. 7 and 8;

FIG. 11 is a plan view showing the principal part in the manufacturing method of the SRAM subsequent to FIGS. 9 and 10;

FIG. 12 is a cross-sectional view showing the principal part in the manufacturing method of the SRAM subsequent to FIGS. 9 and 10;

FIG. 13 is a plan view showing the principal part in the manufacturing method of the SRAM subsequent to FIGS. 11 and 12;

FIG. 14 is a cross-sectional view showing the principal part in the manufacturing method of the SRAM subsequent to FIGS. 11 and 12;

FIG. 15 is a plan view showing the principal part in the manufacturing method of the SRAM subsequent to FIGS. 13 and 14;

FIG. 16 is a cross-sectional view showing the principal part in the manufacturing method of the SRAM subsequent to FIGS. 13 and 14;

FIG. 17 is a plan view showing the principal part in the manufacturing method of the SRAM subsequent to FIGS. 15 and 16;

FIG. 18 is a cross-sectional view showing the principal part in the manufacturing method of the SRAM subsequent to FIGS. 15 and 16;

FIG. 19 is a cross-sectional view showing the principal part in the manufacturing method of the SRAM subsequent to FIGS. 17 and 18;

FIG. 20 is a plan view showing the principal part in the manufacturing method of the SRAM subsequent to FIG. 19;

FIG. 21 is a cross-sectional view showing the principal part in the manufacturing method of the SRAM subsequent to FIG. 19;

FIG. 22 is a cross-sectional view showing the principal part in the manufacturing method of the SRAM subsequent to FIGS. 20 and 21;

FIG. 23 is a cross-sectional view showing the principal part in the manufacturing method of the SRAM subsequent to FIG. 22;

FIG. 24 is a cross-sectional view showing the principal part in the manufacturing method of the SRAM subsequent to FIG. 23;

FIG. 25 is a plan view showing the principal part in the manufacturing method of the SRAM subsequent to FIG. 23;

FIG. 26 is a cross-sectional view showing the principal part in the manufacturing method of the SRAM subsequent to FIGS. 24 and 25;

FIG. 27 is a plan view showing the principal part in the manufacturing method of the SRAM subsequent to FIGS. 24 and 25;

FIG. 28 is a cross-sectional view showing the principal part in the manufacturing method of the SRAM subsequent to FIGS. 26 and 27;

FIG. 29 is a cross-sectional view showing the principal part in the manufacturing method of the SRAM subsequent to FIG. 28;

FIG. 30 is a plan view showing the principal part in the manufacturing method of the SRAM subsequent to FIG. 28;

FIG. 31 is a cross-sectional view showing the principal part in the manufacturing method of the SRAM subsequent to FIGS. 29 and 30;

FIG. 32 is a plan view showing the principal part in the manufacturing method of the SRAM subsequent to FIGS. 29 and 30;

FIG. 33A is a cross-sectional view showing the shape of the trap layer in the SRAM according to another embodiment of the present invention; and

FIG. 33B is a plan view showing the shape of the trap layer in the SRAM according to another embodiment of the present invention.

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiment, and the repetitive description thereof will be omitted.

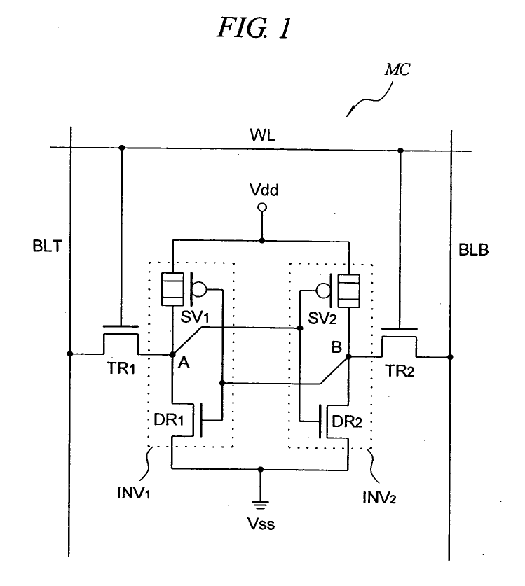

FIG. 1 is an equivalent circuit diagram of a memory cell of the SRAM according to an embodiment of the present invention. This memory cell MC of the SRAM is comprised of two transfer MISFETs (TR₁, TR₂), two driver MISFETs (DR₁, DR₂), and two vertical-type MISFETs (SV₁, SV₂) arranged at the intersection between a pair of complementary data lines (BLT, BLB) and a word line (WL).

Of the six MISFETs constituting the memory cell (MC), the two transfer MISFETs (TR₁, TR₂) and the two driver MISFETs (DR₁, DR₂) are composed of the n channel MISFETs, and the two vertical-type MISFETs (SV₁, SV₂) are composed of the p channel MISFETs. As described later, in the memory cell (MC) in this embodiment, the two vertical-type MISFETs (SV₁, SV₂) are arranged on the two driver MISFETs (DR₁, DR₂) and the transfer MISFETs (TR₁, TR₂) so as to reduce the cell size.

Of the six MISFETs constituting the memory cell (MC), the driver MISFET (DR₁) and the vertical-type MISFET (SV₁) constitute a first inverter INV₁, and the driver MISFET (DR₂) and the vertical-type MISFET (SV₂) constitute a second inverter INV₂. The pair of inverters INV₁ and INV₂ are cross-connected in the memory cell (MC) and constitute a flip-flop circuit functioning as a data storage section in which one bit data is stored. More specifically, the drain of the driver MISFET (DR₁), the drain of the vertical-type MISFET (SV₁), the gate of the driver MISFET (DR₂), and the gate of the vertical-type MISFET (SV₂) are electrically connected and constitute one storage node (A) of the memory cell. Also, the drain of the driver MISFET (DR₂), the drain of the vertical-type MISFET (SV₂), the gate of the driver MISFET (DR₁), and the gate of the vertical-type MISFET (SV₁) are electrically connected and constitute the other storage node (B) of the memory cell.

One input/output terminal of the flip-flop circuit is electrically connected to one of the source and drain of the transfer MISFET (TR₁), and the other input/output terminal is electrically connected to one of the source and drain of the transfer MISFET (TR₂). The other of the source and drain of the transfer MISFET (TR₁) is electrically connected to one data line BLT of the pair of complementary data lines, and the other of the source and drain of the transfer MISFET (TR₂) is electrically connected to the other data line BLB of the pair of complementary data lines. The gate electrodes of the transfer MISFETs (TR₁, TR₂) are electrically connected to the word line (WL).

One terminal of the flip-flop circuit, that is, the sources of the two vertical-type MISFETs (SV₁, SV₂) are electrically connected to a power supply voltage line (Vdd) which supplies the high power supply voltage (Vdd) of, for example, 3 V which is higher than the reference voltage (Vss). The other terminal of the flip-flop circuit, that is, the sources of the two driver MISFETs (DR₁, DR₂) are electrically connected to a reference voltage line (Vss) which supplies the reference voltage (Vss) of, for example, 0 V.

The data retention and the write and read operation in the memory cell (MC) are basically identical to those of the conventional complete CMOS type SRAM. More specifically, in the above-described memory cell (MC), the data is stored by setting the one storage node (A or B) to High and setting the other storage node (A or B) to Low. Also, in the data read operation, the power supply voltage (Vdd) is applied to the selected word line (WL) to turn on the transfer MISFETs (TR₁, TR₂), and the potential difference between the pair of storage nodes (A, B) is read by the complementary data lines (BLT, BLB). Meanwhile, in the data write operation, the power supply voltage (Vdd) is applied to the selected word line (WL) to turn on the transfer MISFETs (TR₁, TR₂), and one of the complementary data lines (BLT, BLB) is connected to the power supply voltage (Vdd) and the other is connected to the reference voltage (Vss). By doing so, the ON and OFF of the driver MISFETs (DR₁, DR₂) are inverted.

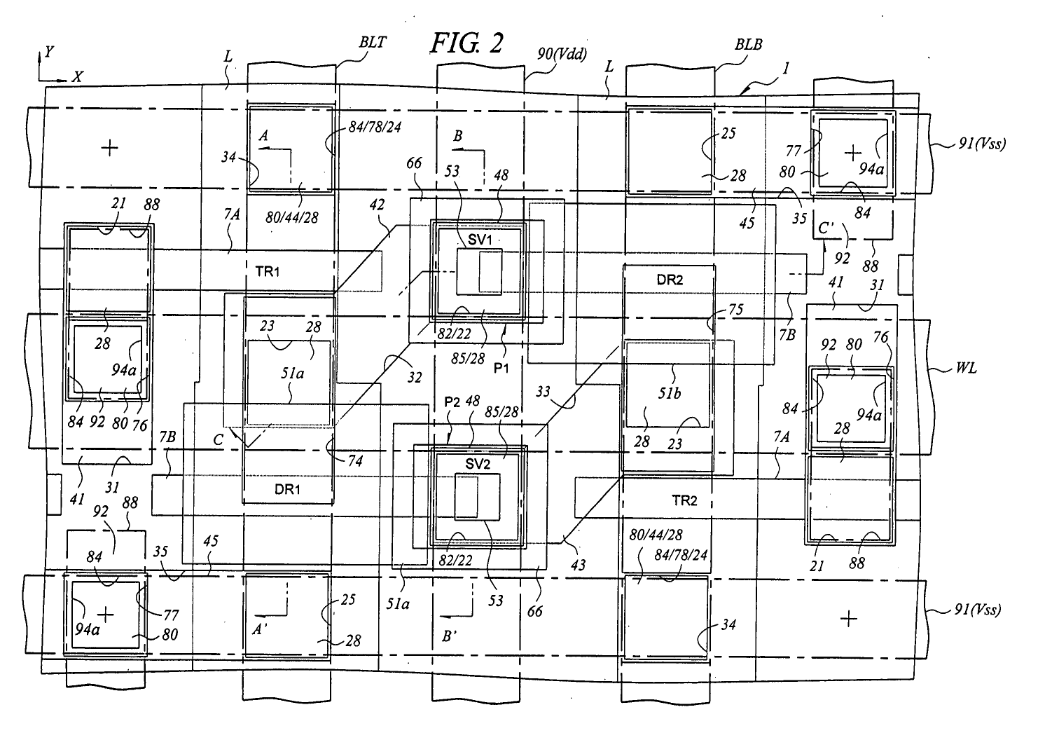

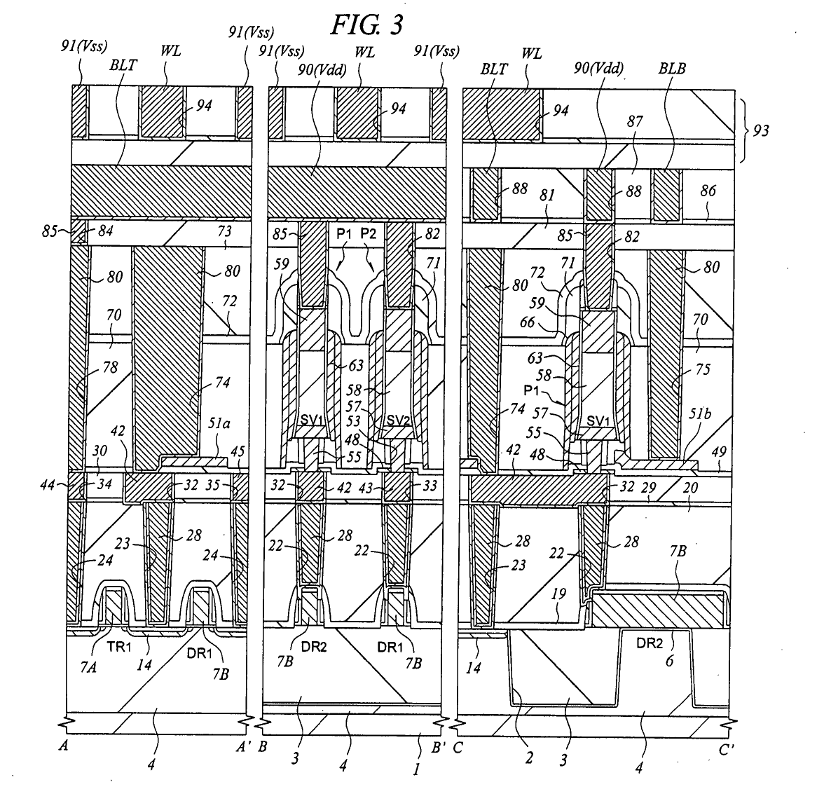

FIG. 2 is a plan view of a semiconductor substrate showing a concrete structure of the memory cell (MC). The left part of FIG. 3 is a cross-sectional view taken along the line A-A′ of FIG. 2, the central part thereof is a cross-sectional view taken along the line B-B′ of FIG. 2, and the right part thereof is a cross-sectional view taken along the line C-C′ of FIG. 2. Note that the rectangular area surrounded by the four (+) marks represents an occupied area of one memory cell. Also, in order to make the memory cell structure easy to see, only the major conductive layers which constitute the memory cell and the connecting regions thereof are shown in FIG. 2, and the illustration of the insulating film formed between the conductive films and the like is omitted.

For example, a p type well 4 is formed in a main surface of the semiconductor substrate 1 made of p type single crystal silicon (hereinafter, referred to as substrate). The two transfer MISFETs (TR₁, TR₂) and the two driver MISFETs (DR₁, DR₂) are formed in the active regions (L₁, L₂) of the p type well 4 defined by the device isolation trench 2. Each of the active regions (L₁, L₂) has an almost rectangular planar pattern extending in a longitudinal direction (Y direction) of FIG. 2. One transfer MISFET (TR₁) and one driver MISFET (DR₁) of the two transfer MISFETs (TR₁, TR₂) and the two driver MISFETs (DR₁, DR₂) are formed in one active region (L₁) and share one of the source and drain thereof. Also, the other transfer MISFET (TR₂) and the other driver MISFET (DR₂) are formed in the other active region (L₂) and share one of the source and drain thereof.

The one transfer MISFET (TR₁) and driver MISFET (DR₁) and the other transfer MISFET (TR₂) and driver MISFET (DR₂) are arranged apart from each other in a lateral direction of FIG. 2 via a device isolation section, and they are located point-symmetrically with respect to a center of the memory cell forming region. Also, the gate electrodes 7B of the driver MISFET (DR₂) and the driver MISFET (DR₁) are arranged so as to extend in a lateral direction (X direction) of FIG. 2. One end portion of the gate electrode 7B in the lateral direction is terminated on the device isolation section between the one transfer MISFET (TR₁) and driver MISFET (DR₁) and the other transfer MISFET (TR₂) and driver MISFET (DR₂), and the vertical-type MISFETs (SV₁, SV₂) are formed on the one end portions.

The vertical-type MISFETs (SV₁, SV₂) are arranged adjacently in the longitudinal direction (Y direction) of FIG. 2, and the power supply voltage lines (Vdd) 90 electrically connected to the sources thereof are arranged on the vertical-type MISFETs (SV₁, SV₂) so as to extend in the longitudinal direction (Y direction) of FIG. 2. In addition, in the same wiring layer as that of the power supply voltage line (Vdd) 90, a pair of complementary data lines BLT and BLB extending in the longitudinal direction (Y direction) of FIG. 2 are arranged with interposing the power supply voltage line (Vdd) 90 therebetween.

The transfer MISFETs (TR₁, TR₂) are comprised of a gate insulating film 6 mainly formed on a surface of the p type well 4, a gate electrode 7A formed on the gate insulating film 6, and n⁺ semiconductor regions 14 (source, drain) formed in the p type well 4 on both sides of the gate electrode 7A. Also, the driver MISFETs (DR₁, DR₂) are comprised of a gate insulating film 6 mainly formed on a surface of the p type well 4, a gate electrode 7B formed on the gate insulating film 6, and n⁺ semiconductor regions 14 (source, drain) formed in the p type well 4 on both sides of the gate electrode 7B.

One of the source and drain of the transfer MISFET (TR₁) is formed integrally with a drain of the driver MISFET (DR₁) in the n⁺ semiconductor region 14, and a contact hole 23 in which a plug 28 is embedded is formed on the n⁺ semiconductor region 14. Also, a contact hole 22 in which a plug 28 is embedded is formed on the gate electrode 7B of the driver MISFET (DR₂), and an intermediate metal layer 42 which connects the plug 28 in the contact hole 22 to the plug 28 in the contact hole 23 is formed on the contact holes 22 and 23. Consequently, the n⁺ semiconductor region 14, which is one of the source and drain of the transfer MISFET (TR₁) and a drain of the driver MISFET (DR₁), is electrically connected to the gate electrode 7B of the driver MISFET (DR₂) via the plugs 28 and 28 and the intermediate metal layer 42.

One of the source and drain of the transfer MISFET (TR₂) is formed integrally with a drain of the driver MISFET (DR₂) in the n⁺ semiconductor region 14, and a contact hole 23 in which a plug 28 is embedded is formed on the n⁺ semiconductor region 14. Also, a contact hole 22 in which a plug 28 is embedded is formed on the gate electrode 7B of the driver MISFET (DR₁), and an intermediate metal layer 43 which connects the plug 28 in the contact hole 22 to the plug 28 in the contact hole 23 is formed on the contact holes 22 and 23. Consequently, the n+semiconductor region 14, which is one of the source and drain of the transfer MISFET (TR₂) and a drain of the driver MISFET (DR₂), is electrically connected to the gate electrode 7B of the driver MISFET (DR₁) via the plugs 28 and 28 and the intermediate metal layer 43. In order to increase the operation speed of the memory cell, the plugs 28 and the intermediate metal layers 42 and 43 for connecting the MISFETs are composed of a metal film such as tungsten (W).

A vertical-type MISFET (SV₁) is formed on one end portion of the gate electrode 7B of the driver MISFET (DR₂), and a vertical-type MISFET (SV₂) is formed on one end portion of the gate electrode 7B of the driver MISFET (DR₁).

The vertical-type MISFET (SV₁) is comprised of a laminated body (P₁) in a shape of rectangular column formed by laminating a lower semiconductor layer (drain) 57, an intermediate semiconductor layer 58, and an upper semiconductor layer (source) 59, and a gate electrode 66 formed on a sidewall of the laminated body (P₁) via a gate insulating film 63. The lower semiconductor layer (drain) 57 of the vertical-type MISFET (SV₁) is connected to the intermediate metal layer. 42 via an underlying plug 55 made of a polycrystalline silicon film and is electrically connected to the n⁺ semiconductor region 14, which is one of the source and drain of the transfer MISFET (TR₁) and a drain of the driver MISFET (DR₁), and the gate electrode 7B of the driver MISFET (DR₂) via the intermediate metal layer 42 and the underlying plugs 28 and 28.

A trap layer 48 composed of a titanium nitride (TiN) film is formed on a part of the surface of the intermediate metal layer 42. This trap layer 48 is arranged so as to surround the plug 55 formed below the lower semiconductor layer (drain) 57 of the vertical-type MISFET (SV₁). The trap layer 48 is formed so as to prevent the undesired high-resistance oxide layer from being formed at the interface between the plug 55 and the intermediate metal layer 42 in the manufacturing process described later.

The vertical-type MISFET (SV₂) is comprised of a laminated body (P₂) in a shape of rectangular column formed by laminating a lower semiconductor layer (drain) 57, an intermediate semiconductor layer 58, and an upper semiconductor layer (source) 59, and a gate electrode 66 formed on a sidewall of the laminated body (P₂) via a gate insulating film 63. The lower semiconductor layer (drain) 57 of the vertical-type MISFET (SV₂) is connected to the intermediate metal layer 43 via an underlying plug 55 made of a polycrystalline silicon film and is electrically connected to the n⁺ semiconductor region 14, which is one of the source and drain of the transfer MISFET (TR₂) and a source of the driver MISFET (DR₂), and the gate electrode 7B of the driver MISFET (DR₁) via the intermediate metal layer 43 and the underlying plugs 28 and 28.

A trap layer 48 composed of a TiN film is formed on a part of the surface of the intermediate metal layer 43. This trap layer 48 is arranged so as to surround the plug 55 formed below the lower semiconductor layer (drain) 57 of the vertical-type MISFET (SV₂). The trap layer 48 is formed so as to prevent the undesired high-resistance oxide layer from being formed at the interface between the plug 55 and the intermediate metal layer 43 in the manufacturing process described later.

In each of the vertical-type MISFETs (SV₁, SV₂), the lower semiconductor layer 57 forms the drain, the intermediate semiconductor layer 58 forms the substrate (channel region), and the upper semiconductor layer 59 forms the source. The lower semiconductor layer 57, the intermediate semiconductor layer 58, and the upper semiconductor layer 59 are composed of a silicon film, and the silicon films constituting the lower semiconductor layer 57 and the upper semiconductor layer 59 are doped with a p type impurity. More specifically, each of the vertical-type MISFETs (SV₁, SV₂) is composed of a p channel MISFET.

Each of the gate electrodes 66 of the vertical-type MISFETs (SV₁, SV₂) is composed of a p type polycrystalline silicon film and is formed in a self-alignment manner with the laminated bodies (P₁,P₂) as described later. Also, the polycrystalline silicon film constituting the plug 55 is composed of a p type polycrystalline silicon film so as to have the same conductivity type as that of the lower semiconductor layer 57 (p type) of the vertical-type MISFETs (SV₁, SV₂).

In the vertical-type MISFETs (SV₁, SV₂), the source, the substrate (channel region), and the drain are laminated in a direction vertical to the main surface of the substrate 1, and the channel current flows in a direction vertical to the main surface of the substrate 1. That is, the so-called vertical channel MISFET is formed. More specifically, the channel length of the vertical-type MISFETs (SV₁, SV₂) extends in the direction vertical to the main surface of the substrate 1, and the channel length is defined by the length between the lower semiconductor layer 57 and the upper semiconductor layer 59 in a direction vertical to the main surface of the substrate 1. Also, the channel width of the vertical-type MISFETs (SV₁, SV₂) is defined by the peripheral length of the laminated bodies (P₁, P₂) in a shape of rectangular column.

The gate electrode 66 of the vertical-type MISFET (SV₁) is electrically connected to a gate read-out electrode 51b formed below it. A through hole 75 in which a plug 80 composed of a metal film such as W is embedded is formed on the gate lead-out electrode 51b. A part of the plug 80 is connected to the intermediate metal layer 43, and the gate electrode 66 of the vertical-type MISFET (SV₁) is electrically connected to the n⁺ semiconductor region 14, which is one of the source and drain of the transfer MISFET (TR₂) and the drain of the driver MISFET (DR₂), and the gate electrode 7B of the driver MISFET (DR₁) via the gate lead-out electrode 51b, the plug 80, the intermediate metal layer 43, and the underlying plugs 28 and 28.

The gate electrode 66 of the vertical-type MISFET (SV₂) is electrically connected to a gate read-out electrode 51a formed below it. A through hole 74 in which a plug 80 is embedded is formed on the gate lead-out electrode 51a. A part of the plug 80 is connected to the intermediate metal layer 42, and the gate electrode 66 of the vertical-type MISFET (SV₂) is electrically connected to the n⁺ semiconductor region 14, which is one of the source and drain of the transfer MISFET (TR₁) and the drain of the driver MISFET (DR₁), and the gate electrode 7B of the driver MISFET (DR₂) via the gate lead-out electrode 51a, the plug 80, the intermediate metal layer 42, and the underlying plugs 28 and 28.

The power supply voltage line (Vdd) 90 is formed on each of the laminated body (P₁) constituting a part of the vertical-type MISFET (SV₁) and the laminated body (P₂) constituting a part of the vertical-type MISFET (SV₂) via an interlayer insulating film. The power supply voltage line (Vdd) 90 is electrically connected to the upper semiconductor layer (source) 59 of the vertical-type MISFET (SV₁) via the plug 85 embedded in the through hole 82 on the laminated body (P₁) and is electrically connected to the upper semiconductor layer (source) 59 of the vertical-type MISFET (SV₂) via the plug 85 embedded in the through hole 82 on the laminated body (P₂).

The complementary data lines BLT and BLB are formed in the same wiring layer as that of the power supply voltage line (Vdd) 90. The power supply voltage line (Vdd) 90 and the complementary lines BLT and BLB extend in parallel with each other in the Y direction of FIG. 2. The complementary data line BLT is arranged so as to overlap with the transfer MISFET (TR₁) and the driver MISFET (DR₁), and the complementary data line BLB is arranged so as to overlap with the transfer MISFET (TR₂) and the driver MISFET (DR₂).

The complementary data line BLT is electrically connected to the other of the source and drain (n⁺ semiconductor region 14) of the transfer MISFET (TR₁) via the plugs 85 and 80, the intermediate metal layer 44, and the plug 28. Also, the complementary data line BLB is electrically connected to the other of the source and drain (n⁺ semiconductor region 14) of the transfer MISFET (TR₂) via the plugs 85 and 80, the intermediate metal layer 44, and the plug 28. The power supply voltage line (Vdd) 90 and the complementary data lines BLT and BLB are composed of, for example, a metal film mainly made of copper (Cu).

The word line (WL) and the reference voltage line (Vss) 91 extending in parallel with each other in the X direction of FIG. 2 are formed on the power supply voltage line (Vdd) 90 and the complementary data lines BLT and BLB via an insulating film 93. The word line (WL) is arranged between the reference voltage lines (Vss) 91 in the Y direction of FIG. 2. The word line (WL) is electrically connected to the gate electrodes 7A of the transfer MISFETs (TR₁, TR₂) via the plugs in the same layers as those of the plugs (85, 80, 28) and the intermediate metal layers in the same layers as those of the intermediate metal layers (43, 44). Similarly, the reference voltage line (Vss) 91 is electrically connected to the n⁺ semiconductor region (source) 14 of the driver MISFETs (DR₁, DR₂) via the plugs in the same-layers as those of the plugs (85, 80, 28) and the intermediate metal layers in the same layers as those of the intermediate metal layers (43, 44). The word line (WL) and the reference voltage line (Vss) 91 are composed of, for example, a metal film mainly made of copper (Cu).

As described above, in the SRAM in this embodiment, of the six MISFETs constituting the memory cell, the two transfer MISFETs (TR₁, TR₂) and the two driver MISFETs (DR₁, DR₂) are formed on the p type well 4 of the substrate 1, and the two vertical-type MISFETs (SV₁, SV₂) are formed on the four MISFETs (TR₁, TR₂, DR₁, DR₂). In this structure, the occupied area of the memory cell is substantially equal to the occupied area of the four MISFETs (TR₁, TR₂, DR₁, DR₂). Therefore, it is possible to reduce the occupied area of the memory cell in comparison to the complete CMOS memory cell comprised of six MISFETs based on the same design rule. Also, different from the complete CMOS memory cell in which the vertical-type p channel MISFETs are formed on the n type well of the substrate, the vertical-type p channel MISFETs (SV₁, SV₂) are formed on the four MISFETs (TR₁, TR₂, DR₁, DR₂) in the SRAM in this embodiment. Therefore, the isolation region between the p type well and the n type well is not required in an occupied area of one memory cell. Consequently, it is possible to further reduce the occupied area of the memory cell, and thus, the high-speed, large-capacity SRAM can be realized.

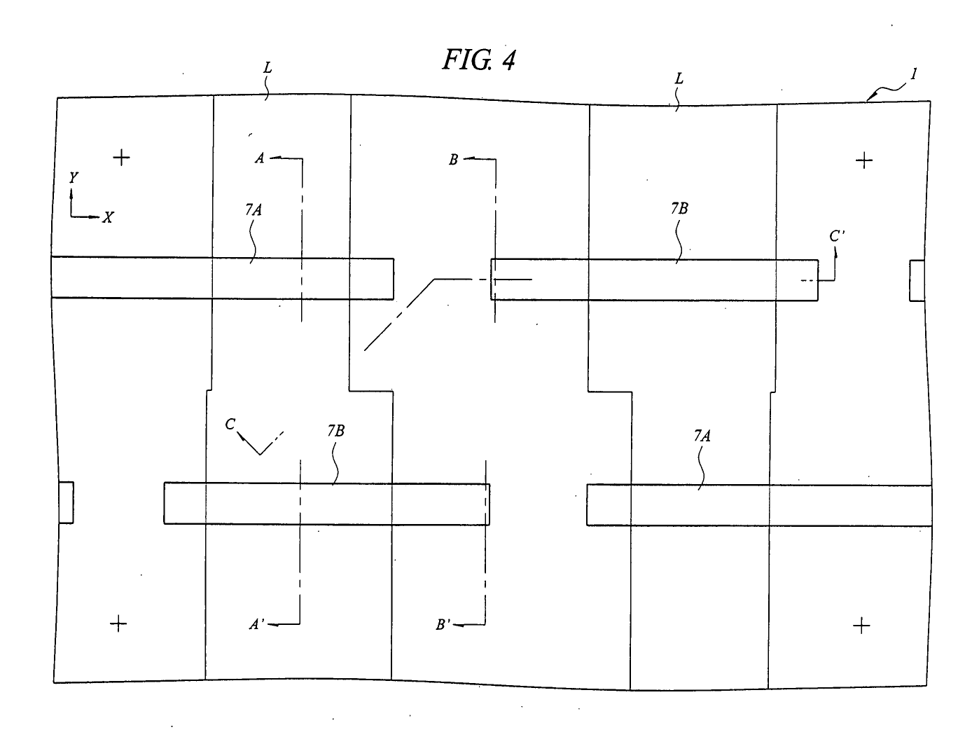

Next, a manufacturing method of the SRAM according to this embodiment will be described with reference to FIGS. 4 to 32. In each of the cross-sectional views for describing the manufacturing method, the part denoted by the symbols A and A′ shows the cross section of the memory cell taken along the line A-A′ in FIG. 2, the part denoted by the symbols B and B′ shows the cross section of the memory cell taken along the line B-B′ in FIG. 2, and the part denoted by the symbols C and C′ shows the cross section of the memory cell taken along the line C-C′ in FIG. 2. Note that the X decoder circuit, the Y decoder circuit, the sense amplifier circuit, the input/output circuit, and the logic circuit which are the peripheral circuits of the SRAM are composed of the n channel MISFETs and the p channel MISFETs. However, the illustration thereof is omitted here.

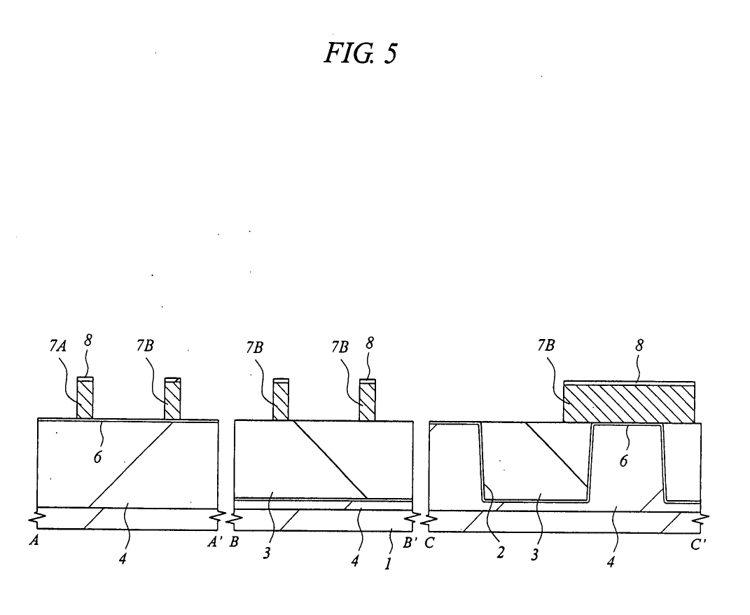

First, as shown in FIGS. 4 and 5, the device isolation trench 2, the p type well 4, and the gate insulating film 6 are formed on the main surface of the substrate 1 made of p type single crystal silicon through the well-known manufacturing process. Thereafter, the gate electrodes 7A and 7B composed of an n type polycrystalline silicon film are formed on the gate insulating film 6. The gate electrodes 7A and 7B are formed in the following manner. That is, after depositing an n type polycrystalline silicon film and a silicon oxide film 8 on the gate insulating film by the CVD method, the silicon oxide film 8 is patterned to have the same planar shape as the gate electrodes 7A and 7B by the dry etching using a photoresist film as a mask, and then, the n type polycrystalline silicon film is dry-etched with using the patterned silicon oxide film 8 as a mask. The gate electrode 7A constitutes a gate electrode of the transfer MISFETs (TR₁, TR₂), and the gate electrode 7B constitutes a gate electrode of the driver MISFETs (DR₁, DR₂).

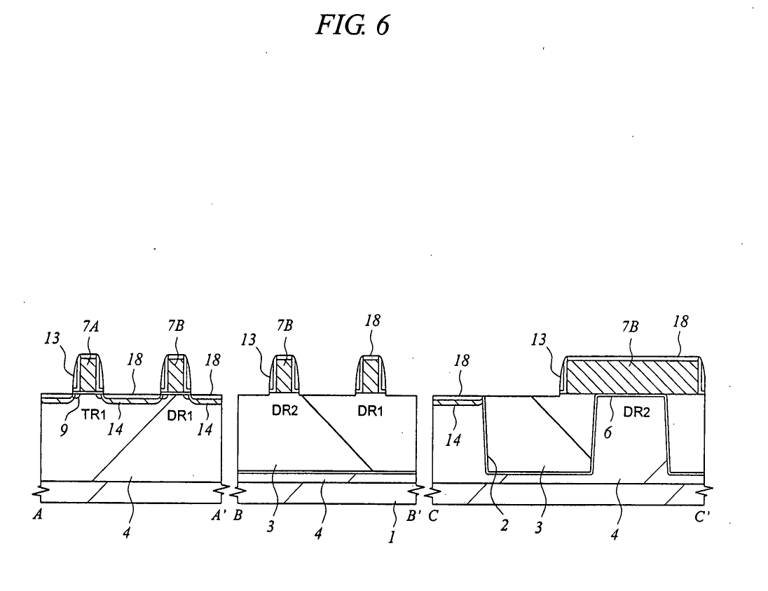

Next, as shown in FIG. 6, the transfer MISFETs (TR₁, TR₂) and the driver MISFETs (DR₁, DR₂) are formed. These MISFETs (TR, TR₂, DR₁, DR₂) are formed in the following manner. First, an n type impurity (phosphorus or arsenic) is ion-implanted into the p type well 4 to form an n semiconductor region 9 with a low impurity concentration, and then, a silicon oxide film and a silicon nitride film are deposited on the substrate 1 by the CVD method. Thereafter, the sidewall spacers 13 are formed on the sidewalls of the gate electrodes 7A and 7B by the anisotropic etching of these insulating films. Subsequently, the n⁺ semiconductor region 14 which constitutes the source and drain of the transfer MISFETs (TR₁, TR₂) and the driver MISFETs (DR₁, DR₂) is formed by the ion implantation of an n type impurity (phosphorus or arsenic) into the p type well 4. Then, after depositing a cobalt (Co) film on the substrate 1 by the sputtering method, the thermal treatment of the substrate 1 is performed to cause the silicide reaction at the interface between the Co film and the gate electrodes 7A and 7B and between the Co film and the substrate 1, and the unreacted Co film is removed by etching. Through the process described above, the transfer MISFETs (TR₁, TR₂) and the driver MISFETs (DR₁, DR₂) in which the Co silicide layer 18 is formed on the surface of the gate electrodes 7A and 7B and on the surface of the source and drain (n⁺ semiconductor region 14) are completed.

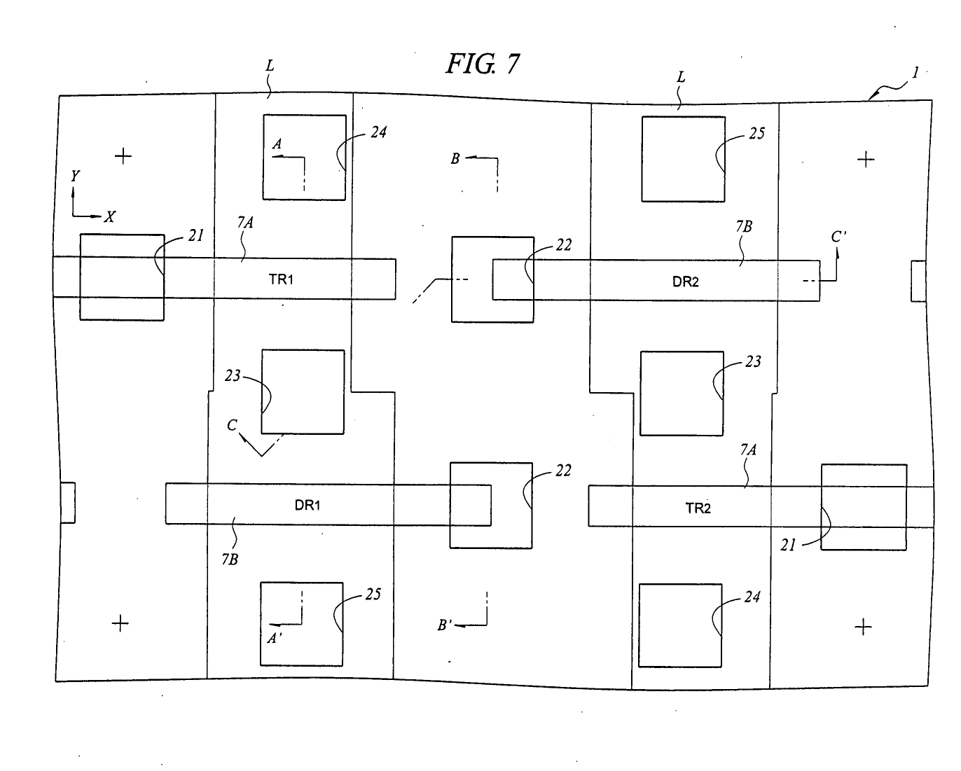

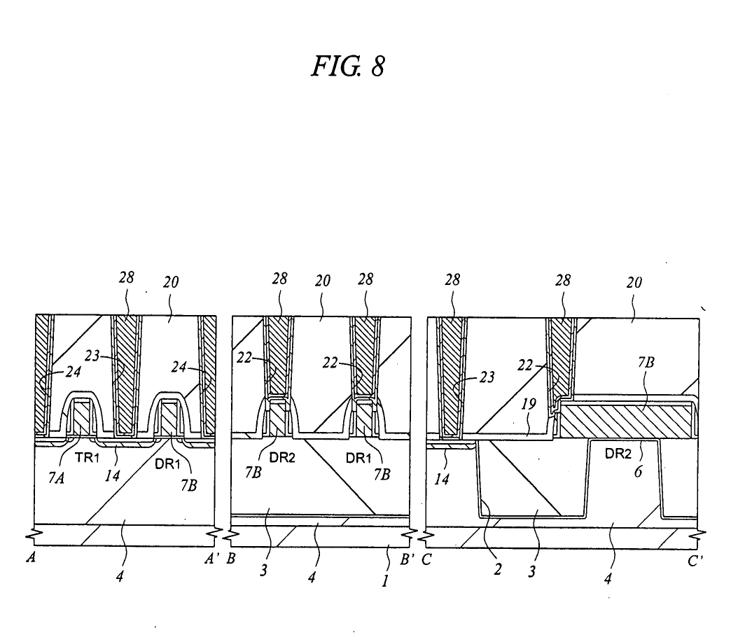

Next, as shown in FIGS. 7 and 8, a silicon nitride film 19 and a silicon oxide film 20 are deposited on the MISFETs (TR₁, TR₂, DR₁, DR₂) by the CVD method, and then, the surface of the silicon oxide film 20 is planarized by the chemical mechanical polishing. Thereafter, the silicon oxide film 20 and the silicon nitride film 19 are dry-etched to form a contact hole 21 on the gate electrode 7A of the transfer MISFETs (TR₁, TR₂) and a contact hole 22 on the gate electrode 7B of the driver MISFETs (DR₁, DR₂). Also, contact holes 23, 24, and 25 are formed on the source and drain (n⁺ semiconductor region 14) of each of the transfer MISFETs (TR₁, TR₂) and the driver MISFETs (DR₁, DR₂). Next, the plugs 28 are formed in the contact holes 21 to 25 in the following manner. That is, after depositing a titanium (Ti) film and a TiN film on the silicon oxide film 20 and in the contact holes 21 to 25 and depositing a TiN film and a W film by the CVD method, the W film, the TiN film, and the Ti film outside the contact holes 21 to 25 are removed by the chemical mechanical polishing.

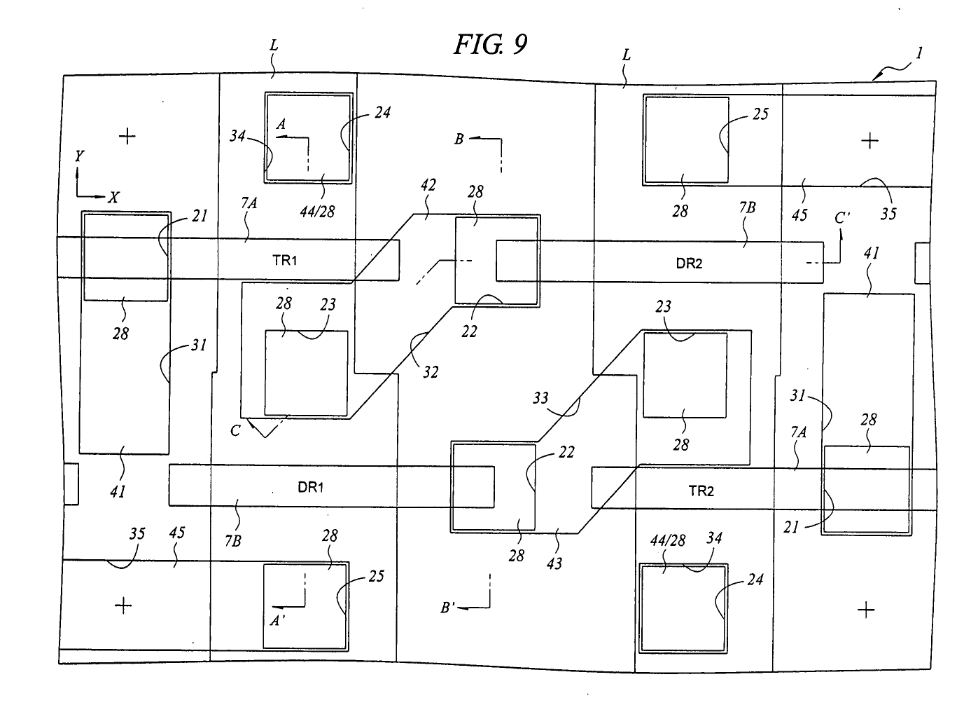

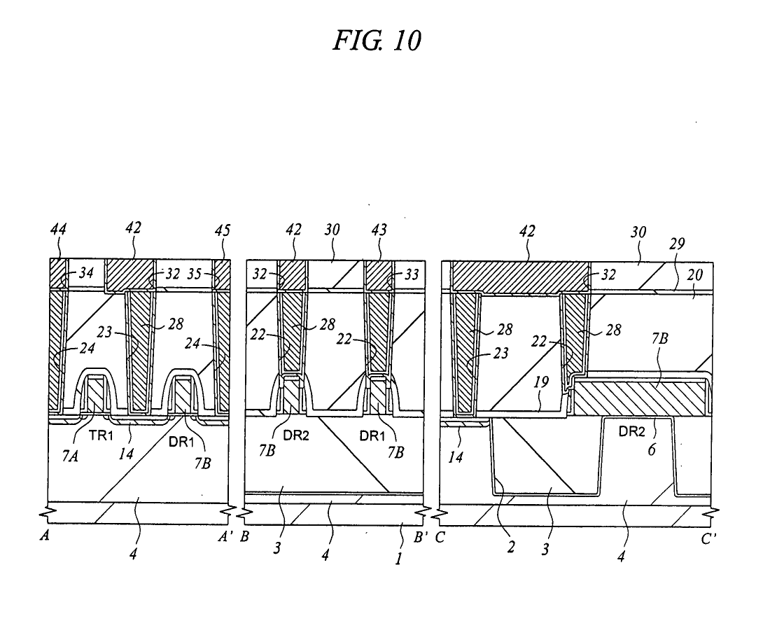

Next, as shown in FIGS. 9 and 10, a silicon nitride film 29 and a silicon oxide film 30 are deposited on the silicon oxide film 20 by the CVD method, and then, trenches 31 to 35 are formed in the silicon oxide film 29 and the silicon nitride film 30 on the contact holes 21 to 25 by the dry etching using a photoresist film as a mask. Thereafter, the intermediate metal layers 41 to 45 are formed in the trenches 31 to 35. The intermediate metal layers 41 to 45 are formed in the following manner. That is, after depositing a W film on the silicon oxide film 30 and in the trenches 31 to 35 by the CVD method, the W film outside the trenches 31 to 35 is removed by the chemical mechanical polishing. Of the intermediate metal layers 41 to 45 formed in the memory array, the intermediate metal layer 41 is used to electrically connect the gate electrode 7A of the transfer MISFETs (TR₁, TR₂) to the word line (WL) formed in the latter process. Also, the intermediate metal layer 44 is used to electrically connect the n⁺ semiconductor region 14 (one of source and drain) of the transfer MISFETs (TR₁, TR₂) to the complementary data lines (BLT, BLB). Furthermore, the intermediate metal layer 45 is used to electrically connect the n⁺ semiconductor region 14 (source) of the driver MISFETs (DR₁, DR₂) to the reference voltage line 91 (Vss) formed in the latter process. The intermediate metal layer 42 is used as a local wiring to electrically connect the n⁺ semiconductor region 14 which constitutes one of the source and drain of the transfer MISFET (TR₁) and the drain of the driver MISFET (DR₁), the gate electrode 7B of the driver MISFET (DR₂), and the lower semiconductor layer 57 (drain) of the vertical-type MISFET (SV₁) formed in the latter process. Also, the intermediate metal layer 43 is used as a local wiring to electrically connect the n⁺ semiconductor region 14 which constitutes one of the source and drain of the transfer MISFET (TR₂) and the drain of the driver MISFET (DR₂), the gate electrode 7B of the driver MISFET (DR₁), and the lower semiconductor layer 57 (drain) of the vertical-type MISFET (SV₂) formed in the latter process.

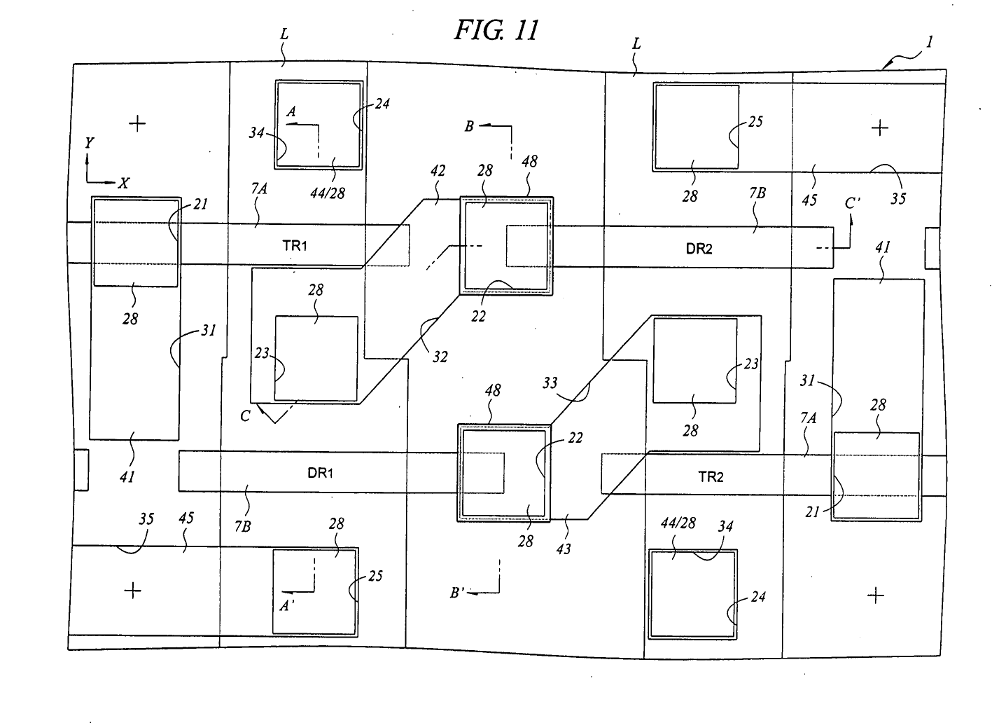

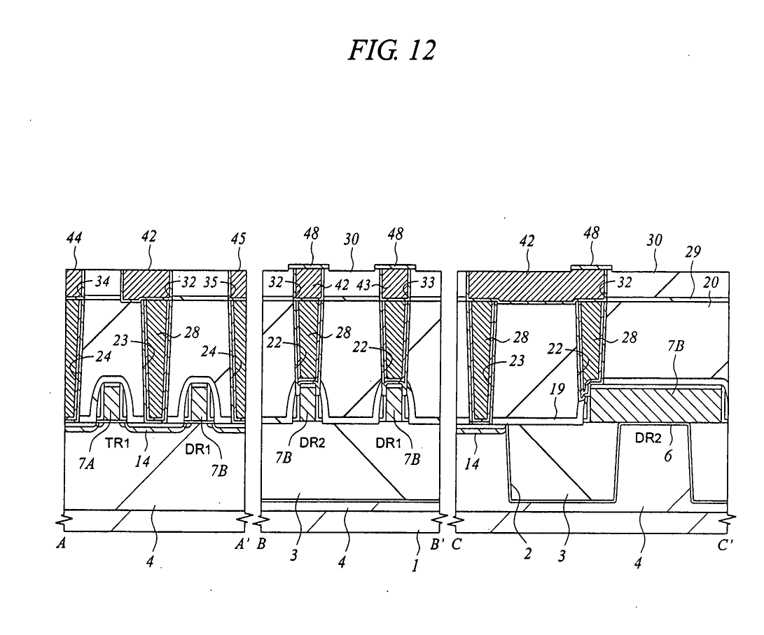

Next, as shown in FIGS. 11 and 12, the trap layer 48 is formed on each surface of the intermediate metal layers 42 and 43. The trap layer 48 is formed in the following manner. That is, after depositing a TiN film on the substrate 1 by the CVD method, the TiN film is patterned by the dry etching using a photoresist film as a mask. The trap layer 48 is arranged below the region in which the vertical-type MISFETs (SV₁, SV₂) are formed in the latter process within the surface region of the intermediate metal layers 42 and 43.

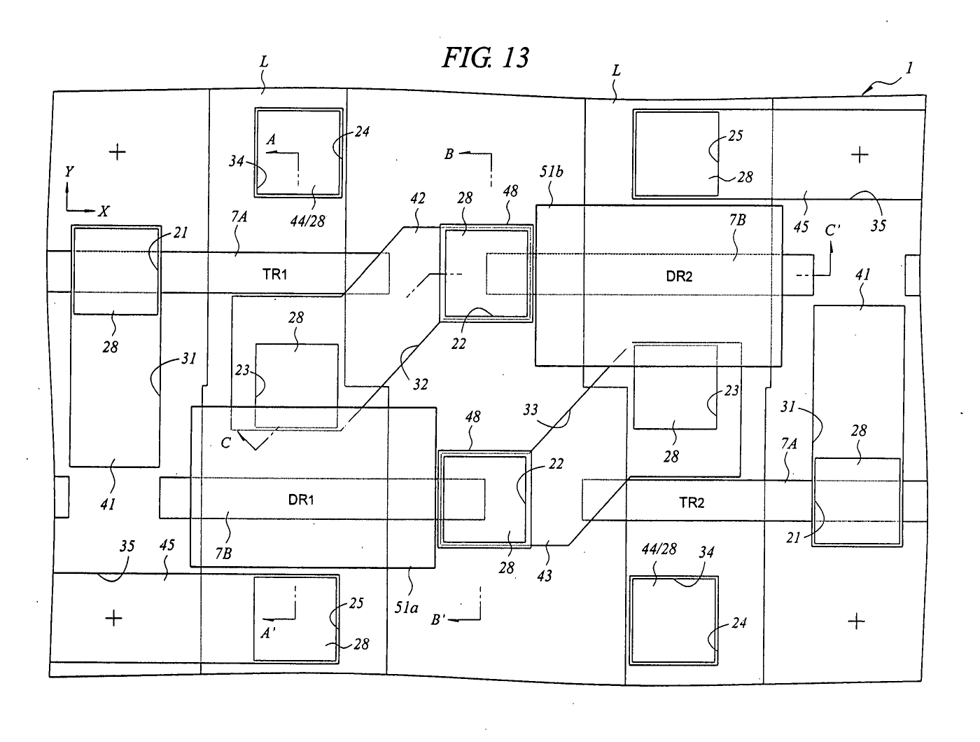

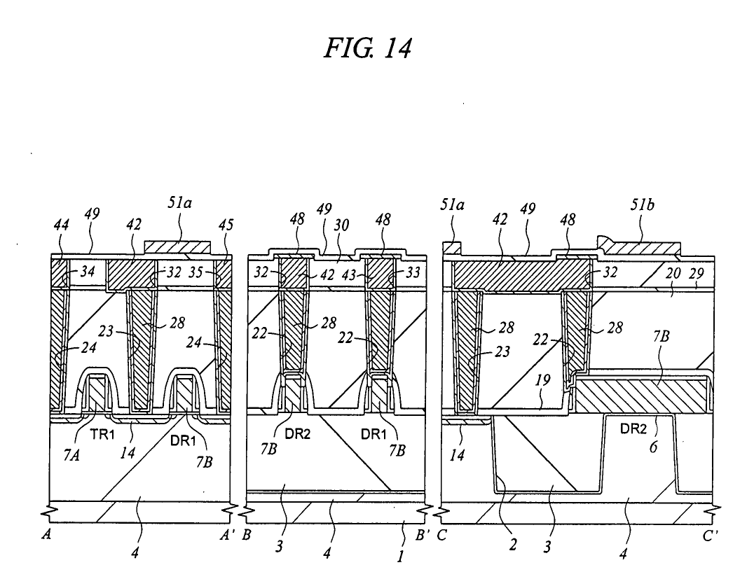

Next, as shown in FIGS. 13 and 14, after depositing a silicon nitride film 49 and a p type polycrystalline silicon film on the substrate 1 by the CVD method, the p type polycrystalline silicon film is patterned by the dry etching using a photoresist film as a mask to form a pair of gate lead-out electrodes 51a and 51b on the silicon nitride film 49. The gate lead-out electrodes 51a and 51b are arranged in the regions adjacent to the vertical-type MISFETs (SV₁, SV₂) formed in the latter process and are used to connect the gate electrode (66) of the vertical-type MISFETs (SV₁, SV₂) to the underlying transfer MISFETs (TR₁, TR₂) and driver MISFETs (DR₁, DR₂). Also, the silicon nitride film 49 is used as an etching stopper film for preventing the underlying silicon oxide film 20 from being etched in the etching of the silicon oxide film (52) deposited on the silicon nitride film 49 in the latter process.

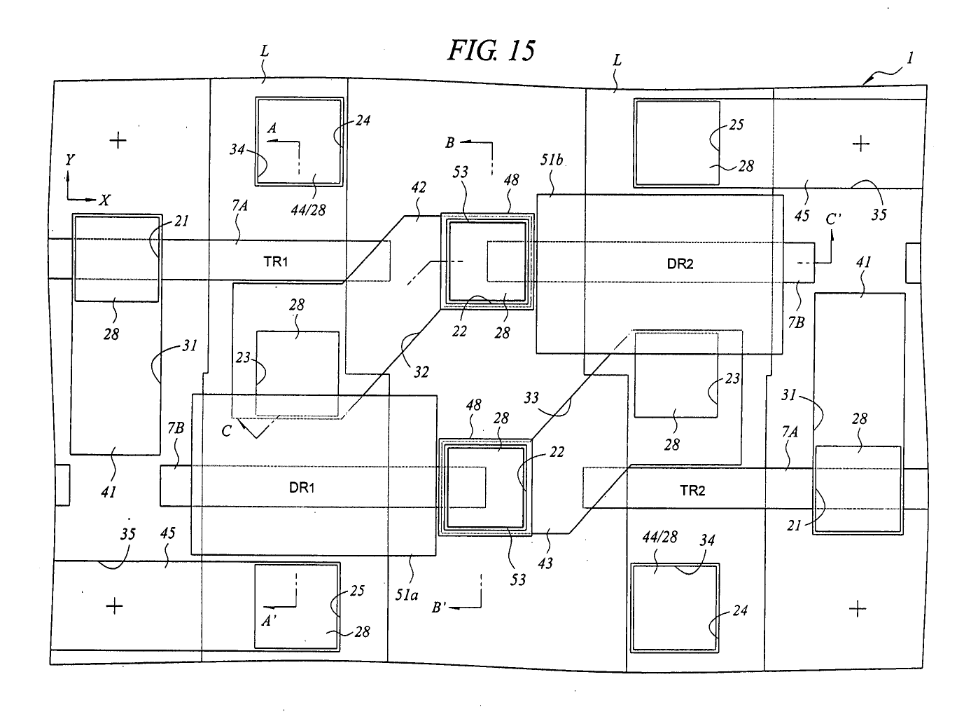

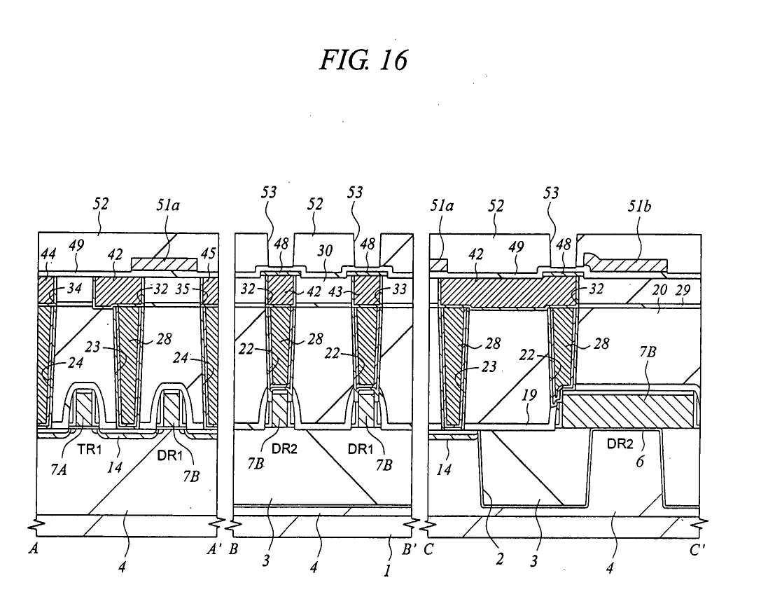

Next, as shown in FIGS. 15 and 16, after depositing a silicon oxide film 52 on the silicon nitride film 49 by the CVD method, the silicon oxide film 52 is dry-etched with using a photoresist film as a mask to form the through holes 53 in the silicon oxide film 52 in the region where the vertical-type MISFETs (SV₁, SV₂) are formed in the latter process.

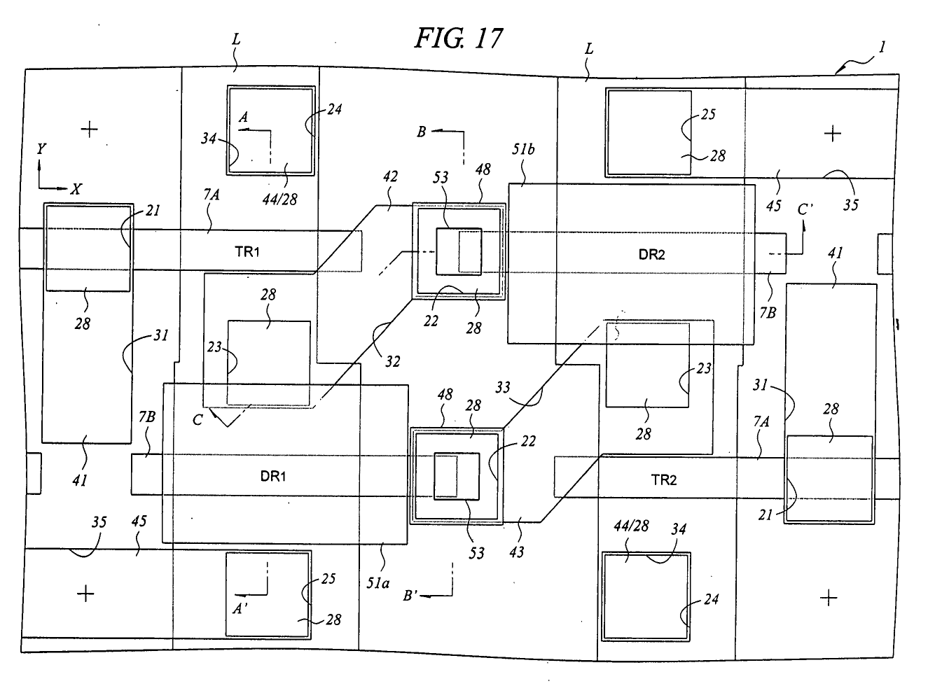

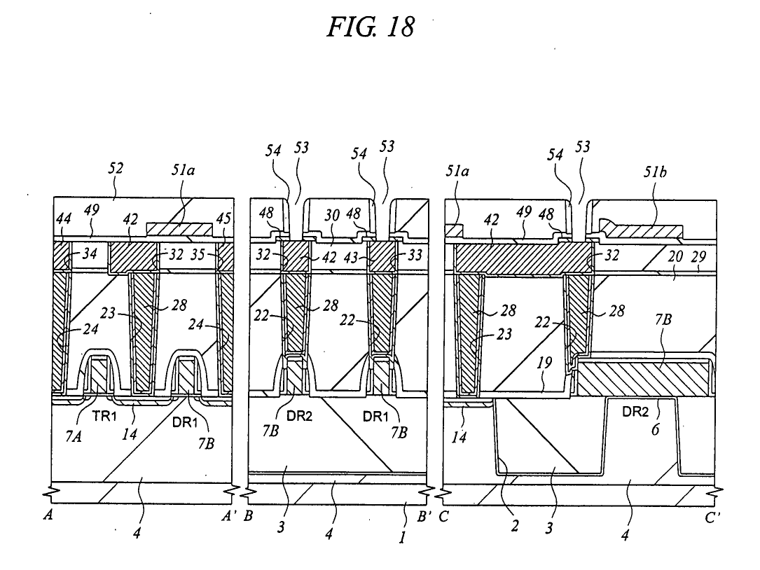

Next, as shown in FIGS. 17 and 18, a sidewall spacer 54 is formed on the sidewall of the through hole 53. The sidewall spacer 54 is formed in the following manner. That is, after depositing a silicon oxide film on the silicon oxide film 52 and in the through holes 53 by the CVD method, the silicon oxide film is anisotropically etched to leave the silicon oxide film on the sidewall of the through holes 53. At this time, by the etching of the silicon nitride film 49 and the trap layer 48 at the bottom of the through holes 53 subsequent to the above-described etching of the silicon oxide film, the intermediate metal layer 42 is exposed at the bottom of one through hole 53, and the intermediate metal layer 43 is exposed at the bottom of the other through hole 53.

Since the sidewall spacer 54 is formed on the sidewall of the through hole 53, the diameter of the through hole 53 can be made smaller than the area of the trap layer 48. Therefore, even if the position of the through hole 53 is misaligned with the trap layer 48 to some extent due to the misalignment of the photomask when the through hole 53 is formed in the silicon oxide film 52, the through hole 53 can be overlapped with the trap layer 48.

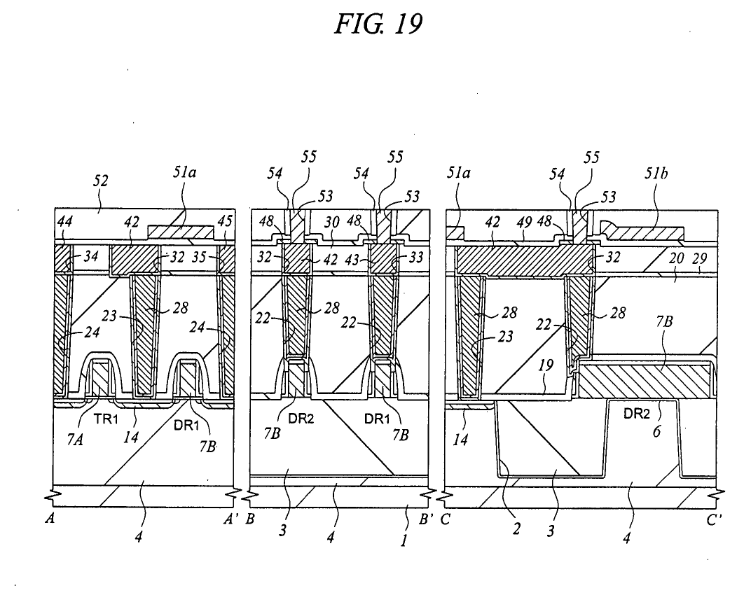

Next, as shown in FIG. 19, a plug 55 composed of a p type polycrystalline silicon film is formed in the through hole 53. The plug 58 is formed in the following manner. That is, after depositing a p type polycrystalline silicon film on the silicon oxide film 52 and in the through holes 53 by the CVD method, the p type polycrystalline silicon film outside the through holes 53 is removed by the chemical mechanical polishing or the etch-back method.

The plug 55 formed in one through hole 53 is electrically connected to the underlying intermediate metal layer 42, and the plug 55 formed in the other through hole 53 is electrically connected to the underlying intermediate metal layer 43. Also, at the bottom of the through holes 53, the entire circumference of the plug 55 is surrounded by the trap layer 48.

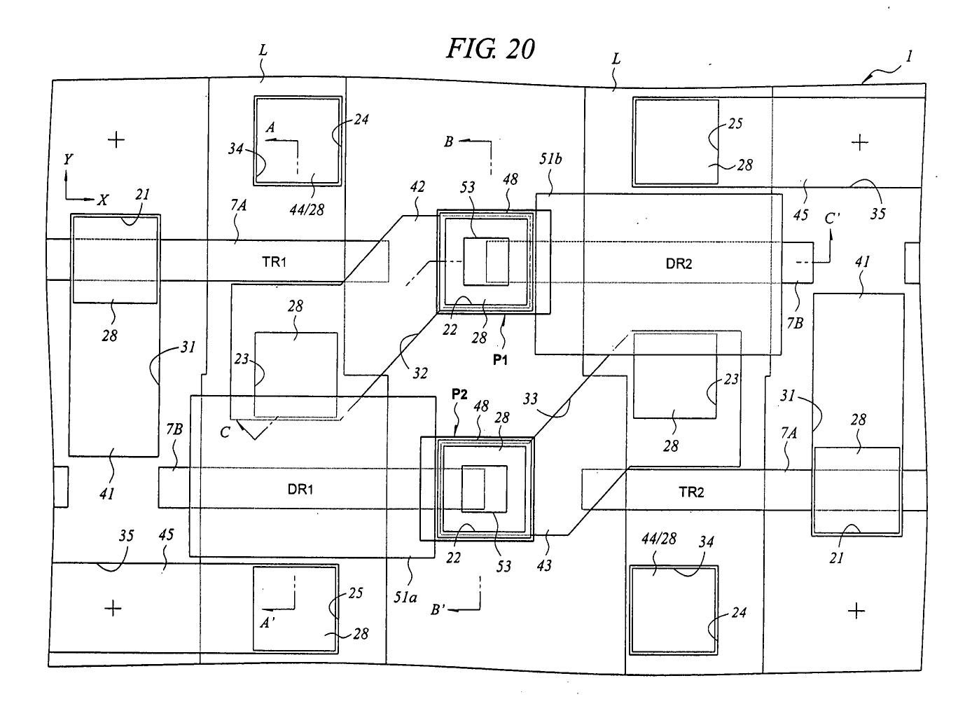

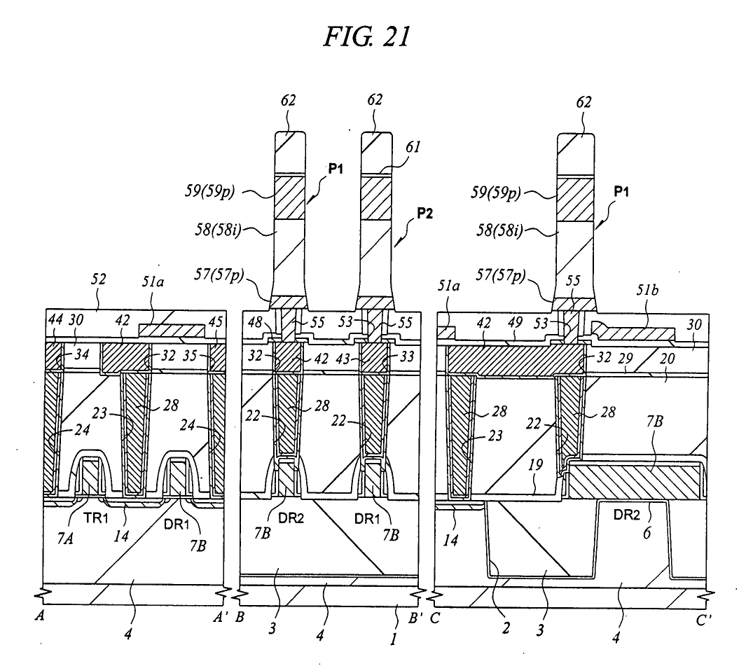

Next, as shown in FIGS. 20 and 21, the laminated bodies (P₁, P₂) in a shape of rectangular column are formed on the through holes 53 in which the plug 58 is embedded. The laminated bodies (P₁, P₂) are formed in the following manner. First, a p type silicon film 57p, a silicon film 58i, and a p type silicon film 59p are formed on the silicon oxide film 52, and then, a silicon oxide film 61 and a silicon nitride film 62 are sequentially deposited on the p type silicon film 59p by the CVD method. Thereafter, the silicon nitride film 62 is dry-etched with using a photoresist film as a mask to leave the silicon nitride film 62 on the region in which the vertical MISFETs (SV₁, SV₂) are formed. Subsequently, the three silicon films (57p, 58i, 59p) are dry-etched with using the silicon nitride film 62 as a mask. By doing so, the laminated bodies (P₁, P₂) in a shape of rectangular column composed of the lower semiconductor layer 57 made of the p type silicon film 57p, the intermediate semiconductor layer 58 made of the silicon film 58i, and the upper semiconductor layer 59 made of the p type silicon film 59p are formed.

The lower semiconductor layer 57 of the laminated body (P₁) constitutes the drain of the vertical-type MISFET (SV₁), and the upper semiconductor layer 59 thereof constitutes the source of the vertical-type MISFET (SV₁). The intermediate semiconductor layer 58 between the lower semiconductor layer 57 and the upper semiconductor layer 59 substantially constitutes the substrate of the vertical-type MISFET (SV₁), and the sidewall thereof constitutes the channel region. Also, the lower semiconductor layer 57 of the laminated body (P₂) constitutes the drain of the vertical-type MISFET (SV₂), and the upper semiconductor layer 59 thereof constitutes the source of the vertical-type MISFET (SV₂). The intermediate semiconductor layer 58 substantially constitutes the substrate of the vertical-type MISFET (SV₂), and the sidewall thereof constitutes the channel region. Also, when viewed two dimensionally, the laminated body (P₁) is arranged so as to overlap with the underlying through hole 53, the trap layer 48, one end portion of the intermediate metal layer 42, the contact hole 22, and one end portion of the gate electrode 7B of the driver MISFET (DR₂). Also, the laminated body (P₂) is arranged so as to overlap with the underlying through hole 53, the trap layer 48, one end portion of the intermediate metal layer 43, the contact hole 22, and one end portion of the gate electrode 7B of the driver MISFET (DR₁).

Note that, when forming the laminated bodies (P₁, P₂), one or plural layers of tunnel insulating film composed of a silicon nitride film is preferably formed adjacent to the interface between the upper semiconductor layer 59 and the intermediate semiconductor layer 58, adjacent to the interface between the lower semiconductor layer 57 and the intermediate semiconductor layer 58, and in a part of the intermediate semiconductor layer 58. By doing so, it is possible to prevent the impurity in the p type silicon films (57p, 59p) constituting the lower semiconductor layer 57 and the upper semiconductor layer 59 from diffusing into the intermediate semiconductor layer 58. Therefore, the performance of the vertical-type MISFETs (SV₁, SV₂) can be improved. In this case, the tunnel insulating film is desirably formed to have a small thickness (about several nm or less) enough to suppress the reduction of the drain current (Ids) of the vertical-type MISFETs (SV₁, SV₂).

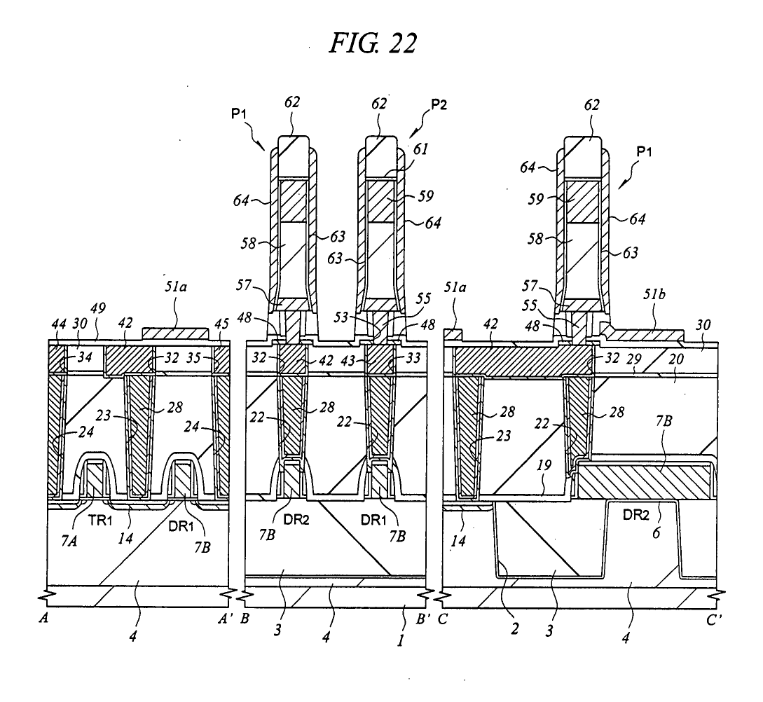

Next, as shown in FIG. 22, a gate insulating film 63 composed of a silicon oxide film is formed on each sidewall surface of the lower semiconductor layer 57, the intermediate semiconductor layer 58, and the upper semiconductor layer 59 which constitute the laminated bodies (P₁, P₂) by the thermal oxidation of the substrate 1. Thereafter, a first polycrystalline silicon layer 64 constituting a part of the gate electrode (66) of the vertical-type MISFETs (SV₁, SV₂) is formed on the sidewall of the laminated bodies (P₁, P₂) and the silicon nitride film 62 formed thereon. The first polycrystalline silicon layer 64 is formed in the following manner. That is, after depositing a p type polycrystalline silicon film on the silicon oxide film 52 by the CVD method, the p type polycrystalline silicon film is anisotropically etched to leave the p type polycrystalline silicon film on the sidewall of the laminated bodies (P₁, P₂) and the silicon nitride film 62.

When the p type polycrystalline silicon film is etched to form the first polycrystalline silicon layer 64, the underlying silicon oxide film 52 is etched subsequent to the etching of the p type polycrystalline silicon film. By doing so, the silicon oxide film 52 in the region other than just below the laminated bodies (P₁, P₂) is removed, and the gate lead-out electrode 51 and the silicon nitride film 49 are exposed. Note that, since the silicon oxide film 52 is left between the lower end portion of the first polycrystalline silicon layer 64 and the gate lead-out electrode 51, the first polycrystalline silicon layer 64 is not electrically connected to the gate lead-out electrode 51.

In addition, in the thermal treatment process for forming the gate insulating film 63 on the sidewall surface of the laminated bodies (P₁, P₂), the water contained in the silicon oxide film 30 around the trenches 31 to 35 in which the intermediate metal layers 41 to 45 are formed is desorbed and moves along the surfaces of the intermediate metal layers 41 to 45. However, since the trap layer 48 surrounding the circumference of the plug 55 is formed on the surfaces of the intermediate metal layers 42 and 43 connected to the plug 55, the water moving along the surfaces of the intermediate metal layers 41 to 45 is captured by the trap layer 48 and does not reach the interface between the plug 55 and the intermediate metal layers 42 and 43.

Consequently, since the high-resistance oxide layer is not formed at the interface between the plug 55 and the intermediate metal layers 42 and 43, the contact resistance between the plug 55 and the intermediate metal layers 42 and 43 can be kept low. As a result, since the current flowing through the memory cell can be controlled to a desired value, the SRAM with good charge retention characteristics can be realized.

In general, the trap layer 48 can be made of a conductive material with the reducing power higher than that of the intermediate metal layers 41 to 45 and that of the metal wiring. Alternatively, it can be made of a conductive material with the water absorbability higher than that of the intermediate metal layers 41 to 45. For example, copper (Cu), silver (II), and molybdenum silicide (MoSi) are available in addition to TiN as the conductive material described above.

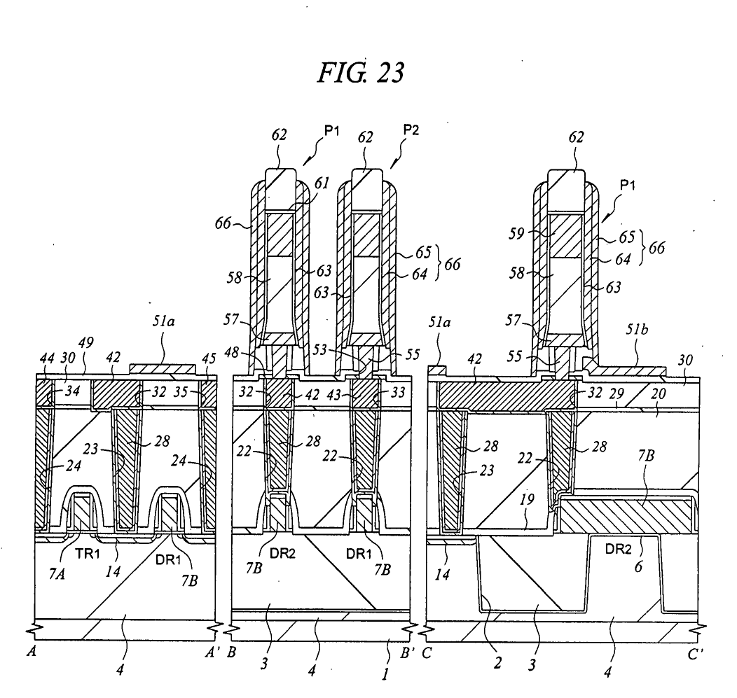

Next, as shown in FIG. 23, a second polycrystalline silicon layer 65 is formed on the surface of the first polycrystalline silicon layer 64. The second polycrystalline silicon layer 65 is formed in the following manner. That is, after depositing a p type polycrystalline silicon film on the silicon oxide film 52 by the CVD method, the polycrystalline silicon film is anisotropically etched to leave the p type polycrystalline silicon film on the surface of the first polycrystalline silicon film. At this time, since the p type polycrystalline silicon film constituting the second polycrystalline silicon layer 65 is also deposited on the sidewall of the silicon oxide film 52 left just below the laminated bodies (P₁, P₂) and on the surface of the gate lead-out electrode 51, the lower end portion of the second polycrystalline silicon layer 65 is brought into contact with the surface of the gate lead-out electrode 51.

Through the process described above, the gate electrode 66 of the vertical-type MISFETs (SV₁, SV₂) composed of the laminated film of the first polycrystalline silicon layer 64 and the second polycrystalline silicon layer 65 is formed on the sidewall of the laminated bodies (P₁, P₂) in a shape of rectangular column and the silicon nitride film 62. This gate electrode 66 is electrically connected to the gate lead-out electrode 51 via the second polycrystalline silicon film 65 which constitutes a part of the gate electrode 66.

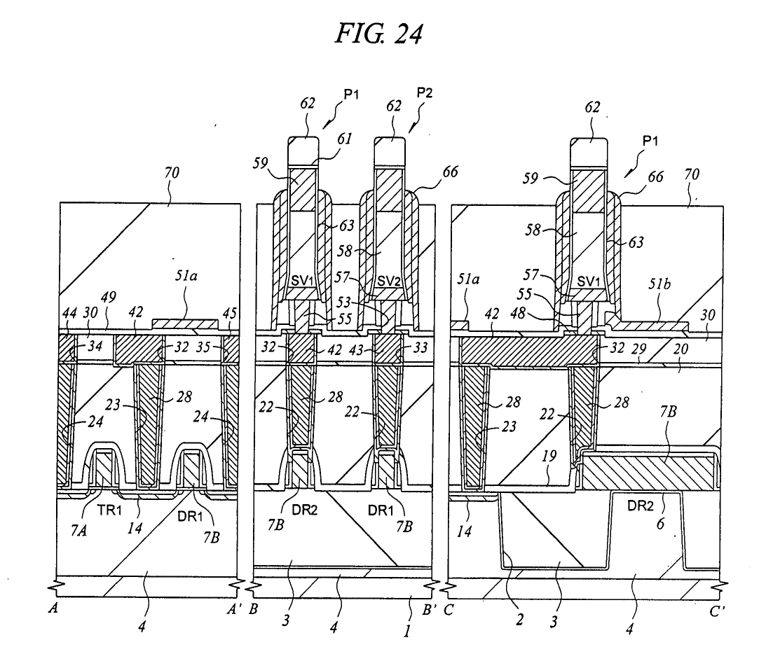

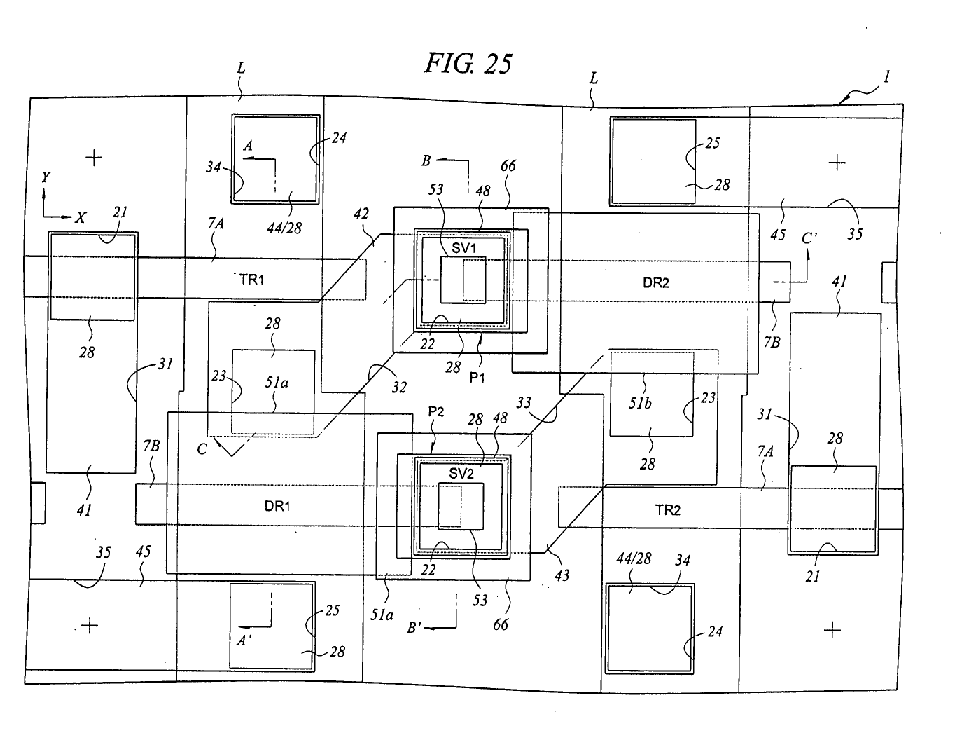

Next, as shown in FIG. 24, a silicon oxide film 70 is deposited on the substrate 1 by the CVD method, and then, the silicon oxide film 70 is etched to lower the surface of the silicon oxide film 70 to the intermediate portion of the laminated bodies (P₁, P₂). Thereafter, the gate electrode 66 formed on the sidewall of the laminated bodies (P₁, P₂) and the silicon nitride film 62 is etched to lower the upper end portion thereof below the upper end portion of the upper semiconductor layer 59. As shown in FIGS. 24 and 25, through the process described above, the vertical-type p channel MISFETs (SV₁, SV₂) comprised of the laminated bodies (P₁, P₂) composed of the lower semiconductor layer 57, the intermediate semiconductor layer 58, and the upper semiconductor layer 59 and the gate insulating film 63 and the gate electrode 66 formed on the sidewall of the laminated bodies (P₁, P₂) are formed in the memory cell region of the memory array.

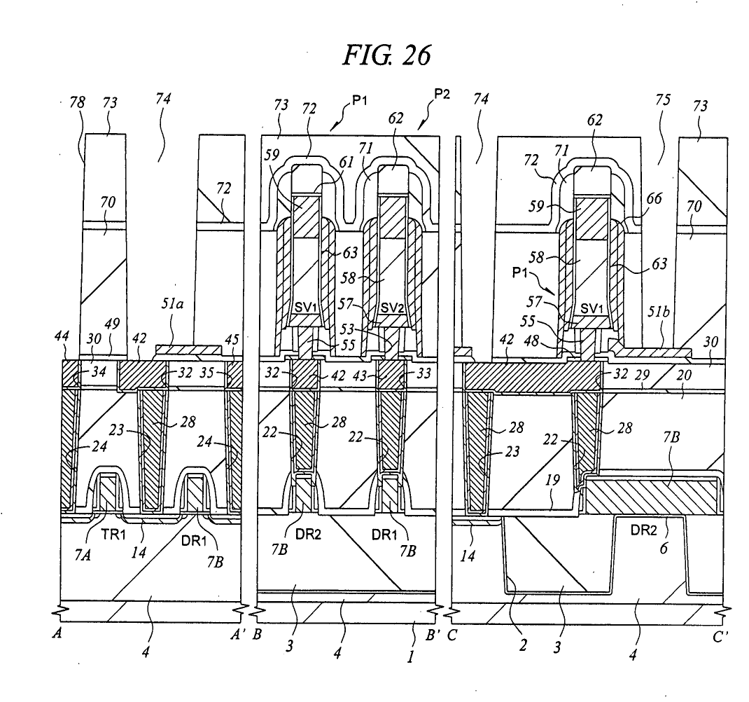

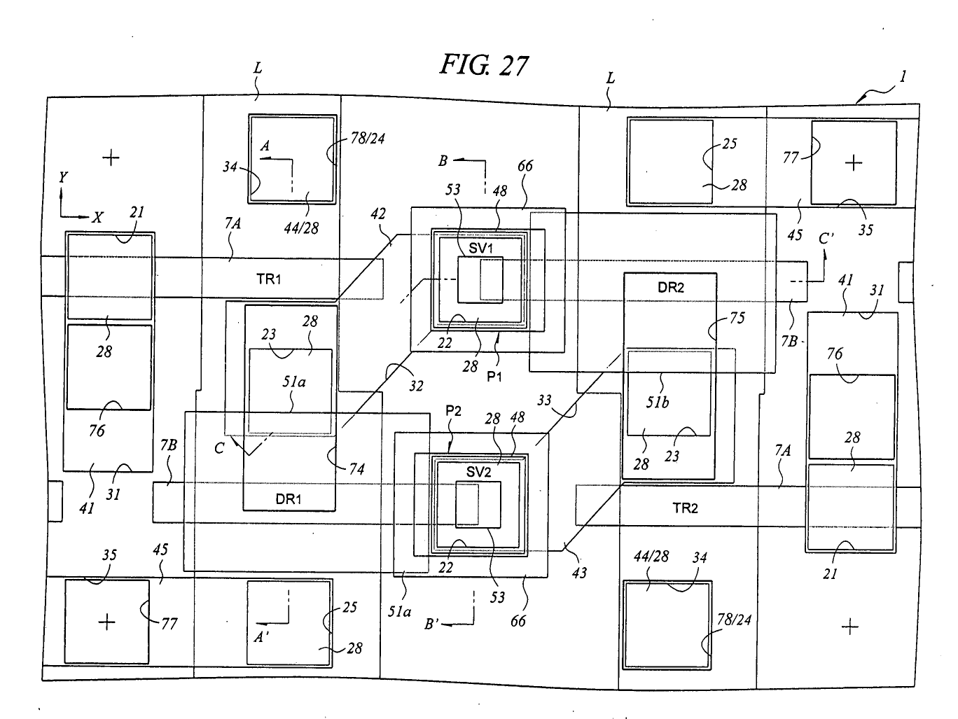

Next, as shown in FIG. 26, after forming a sidewall spacer 71 composed of a silicon oxide film on the sidewall of the gate electrode 66, the upper semiconductor layer 59, and the silicon nitride film 62 of the vertical-type MISFETs (SV₁, SV₂), a silicon nitride film 72 is deposited on the silicon oxide film 70 by the CVD method. The sidewall spacer 71 is formed by the anisotropic etching of the silicon oxide film deposited by the CVD method. Subsequently, a silicon oxide film 73 is deposited on the silicon nitride film 72 by the CVD method, and then, the surface of the silicon oxide film 73 is planarized by the chemical mechanical polishing. Thereafter, the silicon oxide film 73, the silicon nitride film 72, and the silicon oxide film 70 are dry-etched with using a photoresist film as a mask to form a through hole 74 in which the surfaces of the gate lead-out electrode 51a and the intermediate metal layer 42 are exposed and a through hole 75 in which the surfaces of gate lead-out electrode 51b and the intermediate metal layer 43 are exposed. Also, at this time, the through holes 76, 77, and 78 in which the surfaces of the intermediate metal layers 41, 44, and 45 are exposed, respectively, are formed as shown in FIG. 27.

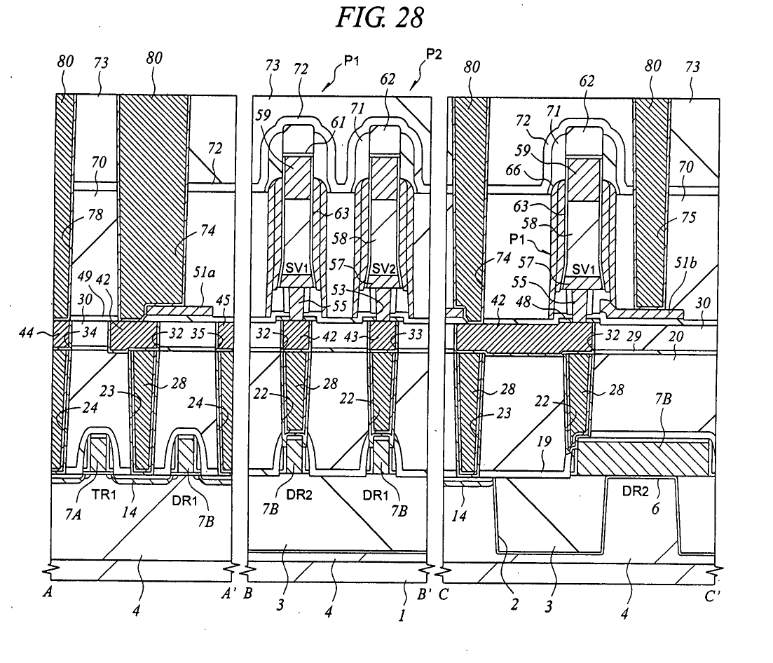

Next, as shown in FIG. 28, a plug 80 is formed in the above-described through holes 74 to 78. The plug 80 is formed in the following manner. That is, after depositing a Ti film and a TiN film on the silicon oxide film 73 and in the through holes 74 to 78 by the sputtering method, a TiN film and a W film are deposited by the CVD method. Thereafter, the W film, the TiN film, and the Ti film outside the through holes 74 to 78 are removed by the chemical mechanical polishing.

Through the process described above, the gate electrode 66 of the vertical-type MISFET (SV₂), the n⁺ type semiconductor region 14, which constitutes one of the source and drain of the transfer MISFET (TR₁) and the source of the driver MISFET (DR₁), and the gate electrode 7B of the driver MISFET (DR₂) are electrically connected via the gate lead-out electrode 51a, the plug 80, the intermediate metal layer 42, and the plug 28. Also, the gate electrode 66 of the vertical-type MISFET (SV₁), the n⁺ type semiconductor region 14 which constitutes one of the source and drain of the transfer MISFET (TR₂) and the source of the driver MISFET (DR₂), and the gate electrode 7B of the driver MISFET (DR₁) are electrically connected via the gate lead-out electrode 51b, the plug 80, the intermediate metal layer 43, and the plug 28. Also, through the process described above, the memory cell comprised of the two transfer MISFETs (TR₁, TR₂), the two driver MISFETs (DR₁, DR₂), and the two vertical-type MISFETs (SV₁, SV₂) is almost completed.

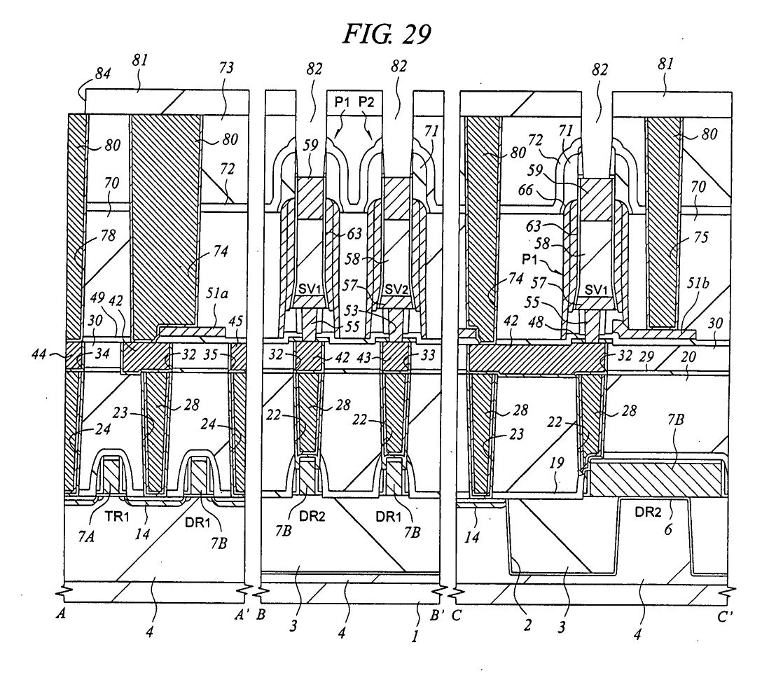

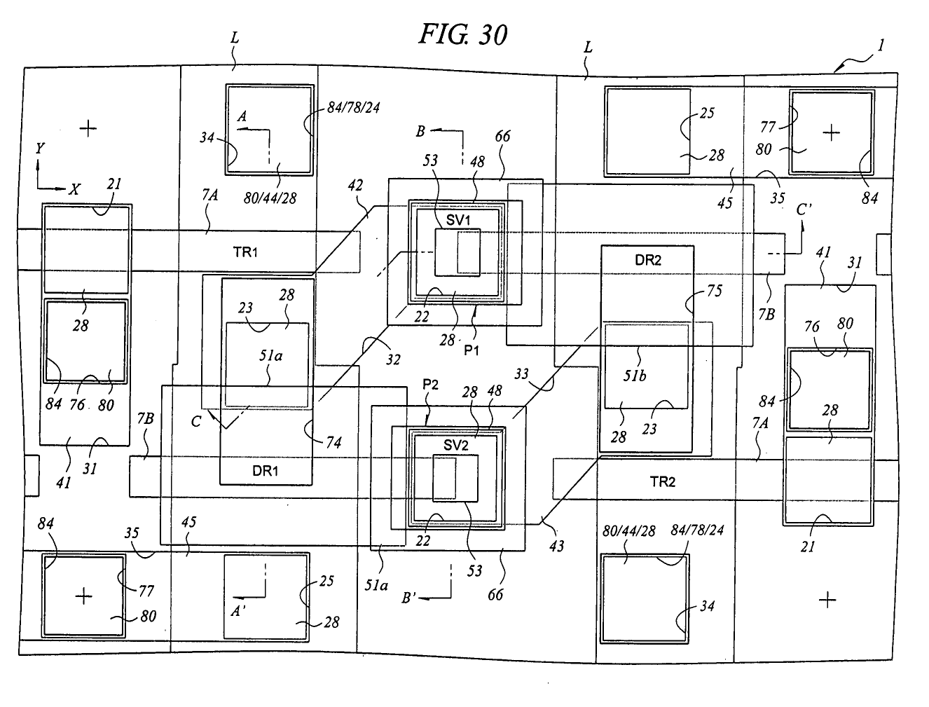

Next, as shown in FIGS. 29 and 30, after depositing a silicon oxide film 81 on the silicon oxide film 73 by the CVD method, the silicon oxide films 81 and 73 and the silicon nitride films 72 and 62 on the laminated bodies (P₁, P₂) are dry-etched to form a through hole 82. Subsequently, the silicon oxide film 81 which covers the through holes 76 to 78 is dry-etched to form a through hole 84.

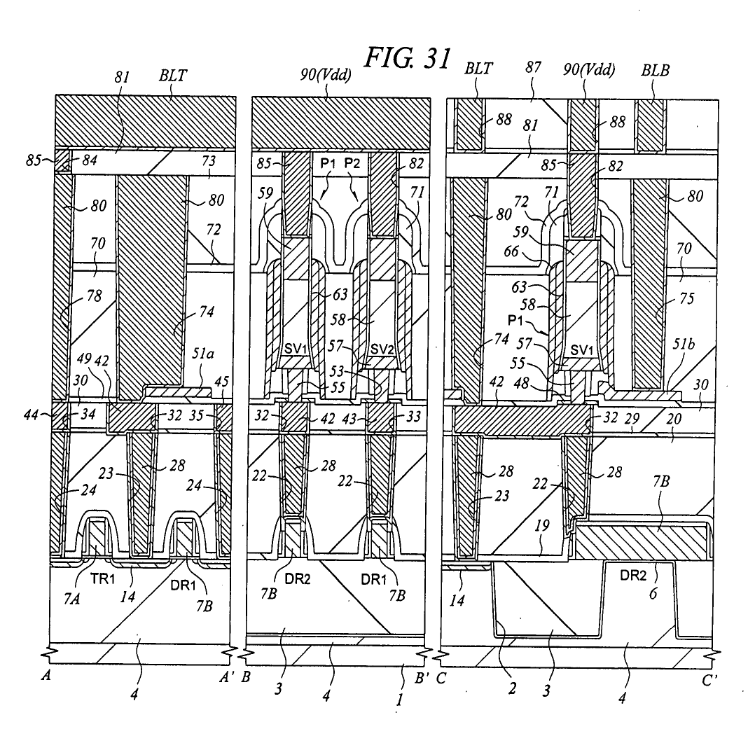

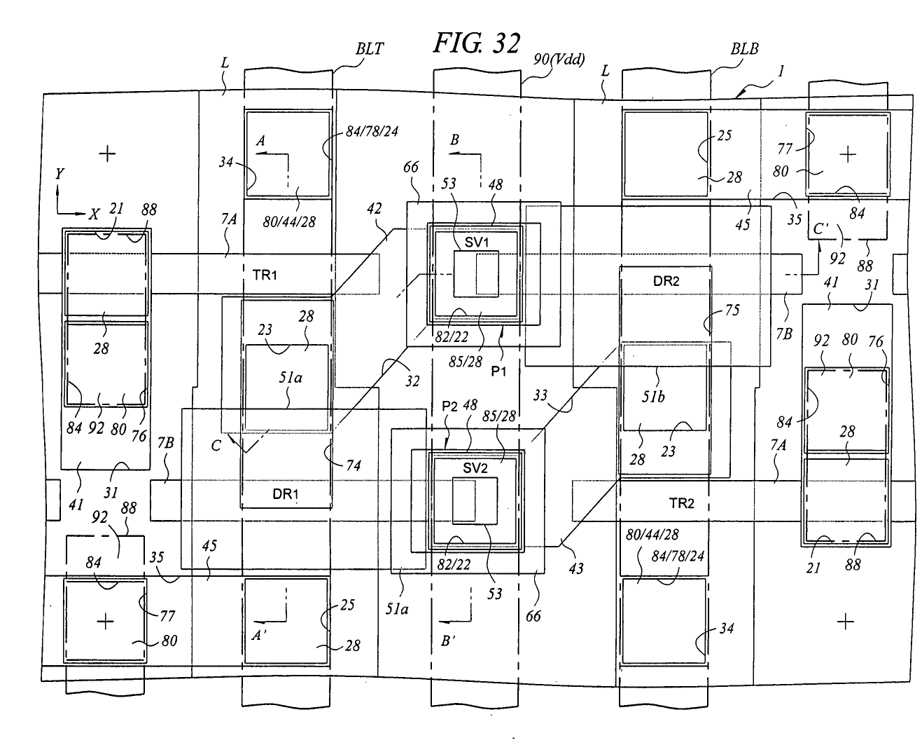

Next, as shown in FIGS. 31 and 32, after forming a plug 85 in the through holes 82 and 84, a power supply voltage line 90 (Vdd) is formed on the plug 85. Also, at this time, the complementary data lines (BLT, BLB) and the lead-out wiring 92 are formed in the same wiring layer as that of the power supply voltage line 90 (Vdd).

The plug 85 is formed in the following manner. That is, after depositing a TiN film on the silicon oxide film 81 and in the through holes 82 and 84 by the sputtering method, a TiN film and a W film are deposited by the CVD method. Thereafter, the TiN film and the W film outside the through holes 82 and 84 are removed by the chemical mechanical polishing.

The power supply voltage line 90 (Vdd), the complementary data lines (BLT, BLB), and the lead-out wiring 92 are formed in the following manner. First, after depositing a silicon carbide film 86 and a silicon oxide film 87 on the silicon oxide film 81 by the CVD method, the silicon oxide film 87 and the silicon carbide film 86 are dry-etched to form a wiring trench 88, and then, a tantalum nitride (TaN) film or a Ta film is deposited on the silicon oxide film 87 and in the wiring trench 88 by the sputtering method. Subsequently, after depositing a Cu film by the sputtering method or the plating method, the unnecessary Cu film and TaN film outside the wiring trench 88 are removed by the chemical mechanical polishing. The power supply voltage line 90 (Vdd) is formed in the wiring trench 88 formed over the plug 85, and the complementary data lines (BLT, BLB) are formed in the wiring trench 88 formed over the plug 80. Also, the lead-out wiring 92 is formed in the four wiring trenches 88 formed in the edge portion of the memory cell.

Thereafter, a reference voltage line 91 (Vss) and a word line (WL) are formed on the wiring layer in which the power supply voltage line 90 (Vdd), the complementary data lines (BLT, BLB), and the lead-out wiring 92 are formed. Then, the SRAM according to this embodiment shown in FIGS. 2 and 3 is completed.

The reference voltage line 91 (Vss) and the word line (WL) are formed in the following manner. First, an insulating film 93 is deposited on the silicon oxide film 87, and then, a wiring trench 94 is formed in this insulating film 93. Subsequently, a Cu film and a TaN film are deposited on the insulating film 93 and in the wiring trench 94 by the above-described method. Thereafter, the unnecessary Cu film and TaN film outside the wiring trench 94 are removed by the chemical mechanical polishing. The insulating film 93 is composed of, for example, a laminated film of a silicon oxide film, a silicon carbide film, and a silicon oxide film deposited by the CVD method.

The reference voltage line 91 (Vss) is electrically connected to each n⁺ semiconductor region 14 (source) of the driver MISFETs (DR₁, DR₂) via the lead-out wiring 92, the plugs 84 and 80, the intermediate metal layer 45, and the plug 28. Also, the word line (WL) is electrically connected to each n⁺ semiconductor region 14 (the other of the source and drain) of the transfer MISFETs (TR₁, TR₂) via the lead-out wiring 92, the plugs 84 and 80, the intermediate metal layer 41, and the plug 28.

In the foregoing, the invention made by the inventors of the present invention has been concretely described based on the embodiments. However, it is needless to say that the present invention is not limited to the foregoing embodiments and various modifications and alterations can be made within the scope of the present invention.

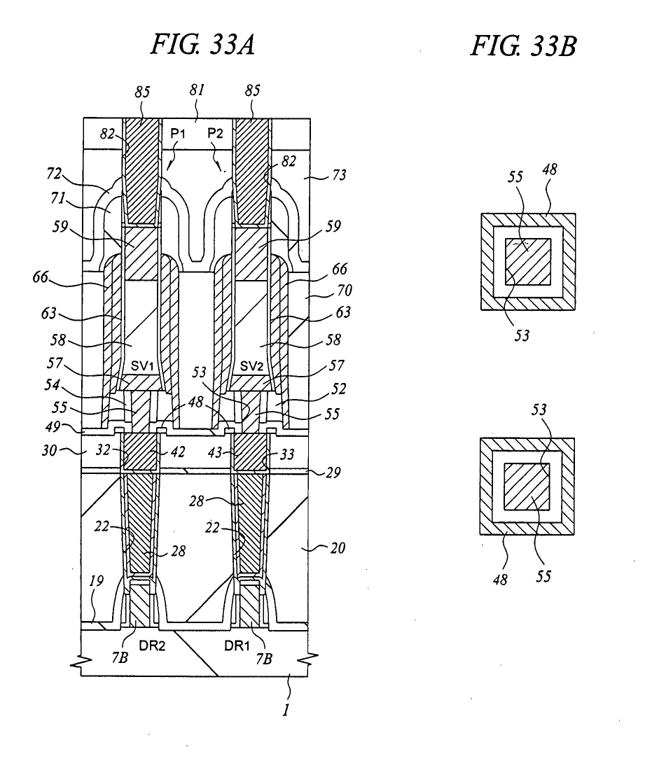

As shown in FIGS. 33A and 33B, it is necessary to form the trap layer 48 so as to surround the plug 55. However, it is not always necessary that the trap layer 48 is brought into contact with the plug 55 like the above-described embodiment.

The present invention is not limited to the SRAM having the vertical-type MISFET, and it can be applied to a semiconductor integrated circuit device having at least a wiring structure in which a plug composed of a conductive film mainly made of silicon is connected to a surface of a metal wiring.

The present invention provides a technique effectively applied to a semiconductor integrated circuit device such as an SRAM having a vertical-type MISFET, in which a plug composed of a conductive film mainly made of silicon is connected to a surface of a metal wiring.

1. A semiconductor integrated circuit device, comprising:
metal wiring formed in a trench formed in a first insulating film on a semiconductor substrate; and
a plug composed of a conductive film mainly made of silicon in a contact hole formed in a second insulating film on said metal wiring,
wherein a bottom portion of said plug is in direct contact with a part of a surface of said metal wiring, and
a trap layer for suppressing a reaction between the silicon constituting said plug and metal constituting said metal wiring is provided on the surface of said metal wiring in a region around said plug.

2. The semiconductor integrated circuit device according to claim 1,
wherein said trap layer is made of titanium nitride.

3. The semiconductor integrated circuit device according to claim 1,
wherein said first insulating film is a silicon oxide film deposited by plasma CVD method.

4. The semiconductor integrated circuit device according to claim 1,
wherein said metal wiring is made of tungsten.

5. The semiconductor integrated circuit device according to claim 1,
wherein said trap layer is made of a conductive material with a reducing power higher than that of said metal wiring.

6. The semiconductor integrated circuit device according to claim 1,
wherein said trap layer is made of a conductive material with water absorbability higher than that of said metal wiring.

7. A semiconductor integrated circuit device, comprising:
a memory cell provided with first and second transfer MISFETs, first and second driver MISFETs, and first and second vertical-type MISFETs, in which said first driver MISFET and said first vertical-type MISFET are cross-connected with said second driver MISFET and said second vertical-type MISFET,
wherein said first and second transfer MISFETs and said first and second driver MISFETs are formed on a main surface of a semiconductor substrate,
said first and second vertical-type MISFETs are formed above said first and second transfer MISFETs and said first and second driver MISFETs,
said first vertical-type MISFET comprises: a source, a channel region, and a drain formed in a first laminated body extending in a direction vertical to the main surface of said semiconductor substrate; and a first gate electrode formed on a sidewall portion of said first laminated body via a gate insulating film,
said second vertical-type MISFET comprises: a source, a channel region, and a drain formed in a second laminated body extending in a direction vertical to the main surface of said semiconductor substrate; and a second gate electrode formed on a sidewall portion of said second laminated body via a gate insulating film,
the drain of said first vertical-type MISFET, a gate electrode of said second driver MISFET, a drain of said first driver MISFET are electrically connected to each other via a first intermediate metal layer,
the drain of said second vertical-type MISFET, a gate electrode of said first driver MISFET, a drain of said second driver MISFET are electrically connected to each other via a second intermediate metal layer,
the first gate electrode of said first vertical-type MISFET is electrically connected to said second intermediate metal layer via a first gate lead-out electrode formed to be in contact with said first gate electrode and a first conductive layer in a first contact hole formed to be in contact with said first gate lead-out electrode and said second intermediate metal layer,
the second gate electrode of said second vertical-type MISFET is electrically connected to said first intermediate metal layer via a second gate lead-out electrode formed to be in contact with said second gate electrode and a second conductive layer in a second contact hole formed to be in contact with said second gate lead-out electrode and said first intermediate metal layer,
said first and second intermediate metal layers are formed in trenches formed in a first insulating film on said semiconductor substrate,
said first intermediate metal layer is electrically connected to the drain of said first vertical-type MISFET via a first plug composed of a conductive film mainly made of silicon embedded in the first contact hole formed in a second insulating film on said first insulating film,
said second intermediate metal layer is electrically connected to the drain of said second vertical-type MISFET via a second plug composed of a conductive film mainly made of silicon embedded in the second contact hole formed in the second insulating film on said first insulating film,
a bottom portion of said first plug is in direct contact with a part of a surface of said first intermediate metal layer,
a bottom portion of said second plug is in direct contact with a part of a surface of said second intermediate metal layer,
a first trap layer for suppressing a reaction between the silicon constituting said first plug and the metal constituting said first intermediate metal layer is provided on a surface of said first intermediate metal layer in a region around said first plug, and
a second trap layer for suppressing a reaction between the silicon constituting said second plug and the metal constituting said second intermediate metal layer is provided on said second intermediate metal layer in a region around said second plug.

8. The semiconductor integrated circuit device according to claim 7,
wherein said first and second trap layers are made of titanium nitride.

9. The semiconductor integrated circuit device according to claim 7,
wherein said first insulating film is a silicon oxide film deposited by plasma CVD method.

10. The semiconductor integrated circuit device according to claim 7,
wherein said first and second intermediate metal layers are made of tungsten.

11. The semiconductor integrated circuit device according to claim 7,
wherein said first laminated body constituting the source, the channel region, and the drain of said first vertical-type MISFET and said second laminated body constituting the source, the channel region, and the drain of said second vertical-type MISFET are made of silicon.

12. A manufacturing method of a semiconductor integrated circuit device, comprising the steps of:
(a) forming a first insulating film on a semiconductor substrate and then forming a trench in said first insulating film;
(b) forming metal wiring in said trench and then forming a trap layer made of a conductive material on a part of a surface of said metal wiring;
(c) forming a second insulating film on said metal wiring and said trap layer and then forming a contact hole reaching the surface of said metal wiring through said second insulating film and said trap layer; and
(d) forming a conductive film mainly made of silicon on said second insulating film and in said contact hole and then removing said conductive film outside said contact hole, thereby forming a plug, a bottom portion of which is in contact with the surface of said metal wiring, in said contact hole.

13. The manufacturing method of a semiconductor integrated circuit device according to claim 12, wherein said trap layer is made of titanium nitride.

14. The manufacturing method of a semiconductor integrated circuit device according to claim 12,
wherein said first insulating film is a silicon oxide film deposited by plasma CVD method.

15. The manufacturing method of a semiconductor integrated circuit device according to claim 12,
wherein said metal wiring is made of tungsten.

16. The manufacturing method of a semiconductor integrated circuit device according to claim 12,
wherein said second insulating film is a laminated film including a silicon nitride film and a silicon oxide film formed thereon.

17. The manufacturing method of a semiconductor integrated circuit device according to claim 12,
wherein said trap layer is made of a conductive material with a reducing power higher than that of said metal wiring.

18. The manufacturing method of a semiconductor integrated circuit device according to claim 12,
wherein said trap layer is made of a conductive material with water absorbability higher than that of said metal wiring.
